(19) United States
(12) Patent Application Publication
(10) Pub. No.: US 2026/0130282 A1
(43) Pub. Date: May 7, 2026

(54) HIGH BANDWIDTH BONDED ASSEMBLY WITH THROUGH-SUBSTRATE VIA STRUCTURES SHIELDED BY GUARD RINGS AND METHODS FOR FORMING THE SAME

(71) Applicant: Sandisk Technologies, Inc., Milpitas, CA (US)

(72) Inventors: Guangyuan LI, Santa Clara, CA (US); Mark KRAMAN, San Jose, CA (US); Fumiaki TOYAMA, Cupertino, CA (US)

(21) Appl. No.: 18/940,325

(22) Filed: Nov. 7, 2024

(51) Int. Cl. H01L 25/18; H01L 23/00; H01L 23/48; H01L 29/06; H10B 41/10; H10B 41/27; H10B 41/30; H10B 41/40; H10B 43/10; H10B 43/27; H10B 43/30; H10B 43/40; H10B 80/00

(52) U.S. Cl. CPC H10W 90/00; H10B 41/10; H10B 41/27; H10B 41/30; H10B 41/40; H10B 43/10; H10B 43/27; H10B 43/30; H10B 43/40; H10B 80/00; H10D 62/102; H10W 20/20; H10W 72/0198; H10W 72/07236; H10W 74/15; H10W 80/312; H10W 80/327; H10W 90/20; H10W 90/28; H10W 90/297; H10W 90/721; H10W 90/722; H10W 90/724; H10W 90/732; H10W 90/734; H10W 90/792

(57) ABSTRACT

A semiconductor structure includes a first unit bonded assembly including a first memory die bonded to a first logic die by direct copper to copper bonding, where that the first logic die includes first through-substrate via structures laterally surrounded by first doped semiconductor well guard rings, and a second unit bonded assembly including a second memory die bonded to a second logic die by direct copper to copper bonding. The first unit bonded assembly is bonded to a second unit bonded assembly by solder balls.

### FIELD

The present disclosure relates generally to the field of semiconductor devices, and particularly to a high bandwidth bonded assembly with through-substrate via structures shielded by guard rings and methods for forming the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprises a vertically bonded stack of multiple unit bonded assemblies that are stacked along a vertical direction. Each unit bonded assembly of the multiple unit bonded assemblies comprises: a memory die including an alternating stack of insulating layers and electrically conductive layers, memory stack structures vertically extending through the alternating stack, a set of memory-die metal interconnect structures embedded within a set of memory-die dielectric material layers, memory-die intra-assembly bonding pads, and memory-die inter-assembly bonding pads; and a logic die including a controller circuit configured to control operation of the memory stack structures in the memory die, a set of logic-die metal interconnect structures embedded within a set of logic-die dielectric material layers, logic-die intra-assembly bonding pads that are bonded to the memory-die intra-assembly bonding pads, logic-die inter-assembly bonding pads, a logic-die substrate on which the controller circuit is located, through-substrate via structures that vertically extend at least through the logic-die substrate, and a doped semiconductor well laterally surrounding at least one of the through-substrate via structures.

According to another aspect of the present disclosure, a semiconductor structure includes a first unit bonded assembly including a first memory die bonded to a first logic die by direct copper to copper bonding, where that the first logic die includes first through-substrate via structures laterally surrounded by first doped semiconductor well guard rings, and a second unit bonded assembly including a second memory die bonded to a second logic die by direct copper to copper bonding. The first unit bonded assembly is bonded to a second unit bonded assembly by solder balls.

According to another aspect of the present disclosure, a method of forming a semiconductor structure includes bonding a first memory die to a first logic die by direct copper to copper bonding to form a first unit bonded assembly, wherein the first logic die comprises first through-substrate via structures laterally surrounded by first doped semiconductor well guard rings; bonding a second memory die to a second logic die by direct copper to copper bonding to form a second unit bonded assembly; and bonding the first unit bonded assembly to a second unit bonded assembly by solder balls.

### BRIEF DESCRIPTION OF THE DRAWINGS

FIG. 1 is a schematic vertical cross-sectional view of a region of an exemplary memory die after formation of a backside dielectric layer, in-process source-level material layers, an alternating stack of insulating layers and sacrificial material layers having stepped surfaces, and a retro-stepped dielectric material portion over a carrier wafer according to an embodiment of the present disclosure.

FIG. 2A is a schematic vertical cross-sectional view of a region of the exemplary memory die after forming memory openings according to an embodiment of the present disclosure.

FIG. 2B is a top-down view of the exemplary memory die of FIG. 2A. The vertical plane A-A′ is the cut plane of the vertical cross-sectional view of FIG. 2A.

FIG. 2C is a top-down view of the exemplary memory die at the processing steps of FIGS. 2A and 2B.

FIGS. 3A-3D are sequential vertical cross-sectional views of a memory opening during formation of a memory opening fill structure according to an embodiment of the present disclosure.

FIG. 4 is a vertical cross-sectional view of a region of the exemplary memory die after formation of memory opening fill structures according to an embodiment of the present disclosure.

FIG. 5A is a vertical cross-sectional view of a region of the exemplary memory die after formation of a contact-level dielectric layer, a patterned hard mask layer, lateral isolation trenches, and discrete through-stack openings according to an embodiment of the present disclosure.

FIG. 5B is a top-down view of a region of the exemplary memory die of FIG. 5A. The vertical plane A-A′ is the cut plane of the vertical cross-sectional view of FIG. 5A.

FIG. 5C is a top-down view of the exemplary memory die at the processing steps of FIGS. 5A and 5B.

FIG. 6 is a vertical cross-sectional view of a region of the exemplary memory die after vertical extension of the discrete through-stack openings according to an embodiment of the present disclosure.

FIG. 7 is a vertical cross-sectional view of a region of the exemplary memory die after formation of sacrificial lateral isolation trench fill structures and sacrificial through-stack opening fill structures according to an embodiment of the present disclosure.

FIG. 8 is a vertical cross-sectional view of a region of the exemplary memory die after removal of the sacrificial lateral isolation trench fill structures according to an embodiment of the present disclosure.

FIG. 9 is a vertical cross-sectional view of a region of the exemplary memory die after formation of a source cavity according to an embodiment of the present disclosure.

FIG. 10 is a vertical cross-sectional view of a region of the exemplary memory die after formation of a source contact layer and dielectric capping liners according to an embodiment of the present disclosure.

FIG. 11 is a vertical cross-sectional view of a region of the exemplary memory die after formation of laterally-extending cavities according to an embodiment of the present disclosure.

FIG. 12 is a vertical cross-sectional view of a region of the exemplary memory die after formation of electrically conductive layers according to an embodiment of the present disclosure.

FIG. 13 is a vertical cross-sectional view of a region of the exemplary memory die after formation of lateral isolation trench fill structures and contact via structures according to an embodiment of the present disclosure.

FIG. 14 is a vertical cross-sectional view of a region of the exemplary memory die after removal of the sacrificial through-stack opening fill structures according to an embodiment of the present disclosure.

FIG. 15 is a vertical cross-sectional view of a region of the exemplary memory die after formation of tubular dielectric spacers and through-stack via structures according to an embodiment of the present disclosure.

FIG. 16 is a vertical cross-sectional view of a region of the exemplary memory die after formation of layer contact via structures, drain contact via structures, and peripheral connection via structures according to an embodiment of the present disclosure.

FIG. 17 is a vertical cross-sectional view of a region of the exemplary memory die after formation of memory-die metal interconnect structures and memory-die bonding pads according to an embodiment of the present disclosure.

FIG. 18A is a vertical cross-sectional view of a region of an exemplary logic die after formation of shallow trench isolation structures and doped semiconductor wells.

FIG. 18B is a top-down view of the region of the exemplary logic die of FIG. 18A.

FIG. 18C is a horizontal cross-sectional view of a region of the exemplary logic die along the horizontal plane C-C′ of FIG. 18A.

FIG. 19 is a vertical cross-sectional view of a region of the exemplary logic die after formation of controller semiconductor devices, lower-level logic-die dielectric material layers, and lower-level logic-die metal interconnect structures according to an embodiment of the present disclosure.

FIG. 20A is a vertical cross-sectional view of a region of the exemplary logic die after formation of through-substrate via structures according to an embodiment of the present disclosure.

FIG. 20B is a horizontal cross-sectional view of a region of the exemplary logic die along the horizontal plane B-B′ of FIG. 20A.

FIG. 21 is a vertical cross-sectional view of a region of the exemplary logic die after formation of upper-level logic dielectric material layers and upper-level logic-die metal interconnect structures according to an embodiment of the present disclosure.

FIG. 22 is a vertical cross-sectional view of a region of a first exemplary bonded wafer assembly of a memory wafer and a logic wafer according to an embodiment of the present disclosure.

FIG. 23 is a vertical cross-sectional view of a region of the first exemplary bonded wafer assembly after removal of a carrier wafer from the memory die according to an embodiment of the present disclosure.

FIG. 24 is a vertical cross-sectional view of a region of the first exemplary bonded wafer assembly after formation of backside via openings according to an embodiment of the present disclosure.

FIG. 25 is a vertical cross-sectional view of a region of the first exemplary bonded wafer assembly after memory-die backside metal interconnect structures according to an embodiment of the present disclosure.

FIG. 26A is a vertical cross-sectional view of a region of the first exemplary bonded wafer assembly after formation of a memory-die backside dielectric material layers and memory-die inter-assembly bonding pads according to an embodiment of the present disclosure.

FIG. 26B is a top-down view of the first exemplary bonded wafer assembly of FIG. 26A.

FIG. 27 is a vertical cross-sectional view of a region of the first exemplary bonded wafer assembly after thinning the substrate semiconductor layer of the logic die from the backside according to an embodiment of the present disclosure.

FIG. 28 is a vertical cross-sectional view of a region of the first exemplary bonded wafer assembly after formation of logic-die inter-assembly bonding pads embedded in a logic-die backside dielectric layer according to an embodiment of the present disclosure.

FIG. 29 is a vertical cross-sectional view of region of a first singulated composite die including a single unit bonded assembly according to an embodiment of the present disclosure.

FIG. 30 is a vertical cross-sectional view of a region of a second exemplary bonded wafer assembly according to an embodiment of the present disclosure.

FIG. 31 is a vertical cross-sectional view of region of a second singulated composite die including two unit bonded assemblies according to an embodiment of the present disclosure.

FIG. 32 is a vertical cross-sectional view of a region of a third exemplary bonded wafer assembly according to an embodiment of the present disclosure.

FIG. 33 is a vertical cross-sectional view of region of a third singulated composite die including two unit bonded assemblies according to an embodiment of the present disclosure.

FIG. 34A is a vertical cross-sectional view of a first composite bonded assembly according to an embodiment of the present disclosure.

FIG. 34B is a vertical cross-sectional view of a second composite bonded assembly according to an embodiment of the present disclosure.

### DETAILED DESCRIPTION

As discussed above, the embodiments of the present disclosure are directed to a high bandwidth bonded assembly with through-substrate via structures shielded by guard rings and methods for forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Wafer-to-wafer (W2W) and die-to-wafer (D2W) bonding techniques are used to form bonded assemblies of stacked memory dies. Wafer-to-wafer bonding offers higher throughput and lower manufacturing costs. According to an aspect of the present disclosure, wafer-to-wafer bonding is employed to bond multiple memory wafers and multiple logic wafers. Each memory wafer supports a respective array of memory dies, and each logic wafer supports a respective array of logic (e.g., controller/peripheral) dies configured to control operation of a memory die.

According to an aspect of the present disclosure, high memory density, high performance, and low manufacturing cost can be simultaneously achieved bonding memory and logic wafers, dicing the bonded wafers to generate multiple unit bonded assemblies of a memory die and a logic die that are bonded to each other, and then vertically stacking multiple unit bonded assemblies. Each unit bonded assembly includes a vertically bonded pair of a memory die and a logic (e.g., controller) die configured to control the operation of the memory die. Plural unit bonded assemblies can be vertically stacked using through-substrate via structures that extend through the substrate of the logic dies and bonding pads embedded within a backside dielectric layer.

Each unit bonded assembly comprises a bonded pair of a memory die and logic die configured to control operation of the memory die. Plural unit bonded assemblies can be vertically stacked using through-substrate via structures vertically extending through the logic dies and intra-assembly bonding pads which are embedded within a respective backside dielectric layer. In one embodiment, electrically grounded doped semiconductor wells (i.e., guard rings) are located around the through-substrate via structures to provide electromagnetic shielding for electrical signals that pass through the through-substrate via structures. Thus, the electrically grounded doped semiconductor wells enhance the signal integrity for vertical signal paths through the vertically bonded stack.

The vertically bonded stack of multiple unit bonded assemblies comprises multiple memory dies and multiple logic dies that are vertically bonded to each other using metal-to-metal bonding. such as copper-to-copper bonding. Further, dielectric-to-dielectric bonding may optionally be used between each vertically-neighboring pair of dielectric material layers between memory and logic dies that are bonded to each other. The various aspects of embodiments of the present disclosure are now described with reference to accompanying drawings.

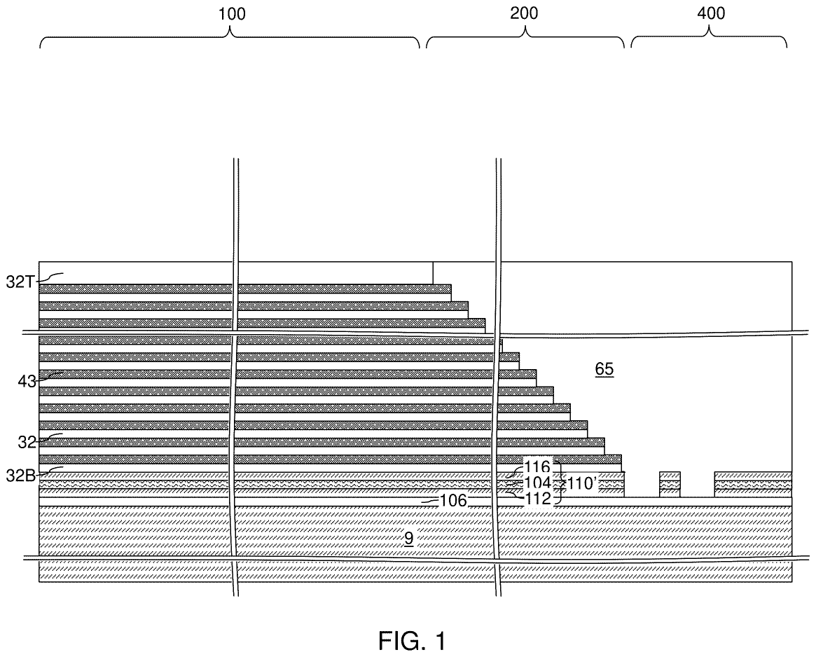

Referring to FIG. 1, an exemplary memory die according to an embodiment of the present disclosure is illustrated during a manufacture process. The exemplary memory die comprises a carrier wafer 9, which may be a semiconductor substrate, a dielectric substrate, or a conductive substrate. For example, the carrier wafer 9 may comprise a commercially available silicon wafer. Alternatively, the carrier wafer 9 may comprise any material that may be removed selectively to the materials of a first memory-die backside dielectric layer 106 and a retro-stepped dielectric material portion 65 to be subsequently formed.

According to an aspect of the present disclosure, a commercially available wafer, such as a semiconductor (e.g., silicon) wafer, a glass wafer, or an alternative disposable wafer having a diameter in a range from 100 mm to 450 mm, may be employed as the carrier wafer 9 to form the exemplary memory die. For example, the carrier wafer 9 may be a commercially available single crystalline silicon wafer. A plurality of memory dies, such as a two-dimensional array of memory dies, can be formed on the wafer 9. In this case, the exemplary memory die may be one of the memory dies that are formed on the wafer 0, and a two-dimensional array of the exemplary memory die described below may be formed over the wafer 9. By forming a two-dimensional array of memory dies, a wafer-to-wafer bonding process can be subsequently performed employing the wafer 9 which supports a two-dimensional array of memory dies. A wafer 9 supporting a two-dimensional array of memory dies is referred to as a memory wafer. Thus, it should be understood that the structural features for the exemplary memory die described herein may be formed on all or a portion of the memory dies on the wafer 9 at the same time.

A dielectric material layer can be formed on a top surface of the carrier wafer 9. The dielectric material layer can be subsequently employed as a stopping material layer for a process that removes the carrier wafer 9, and is herein referred to as a first memory-die backside dielectric layer 106, or as a stopper dielectric layer. The first memory-die backside dielectric layer 106 comprises and/or consists essentially of an inorganic dielectric material, such as undoped silicate glass (i.e., silicon oxide), a doped silicate glass, or silicon nitride. If a polishing process such as a chemical mechanical polishing process is employed to subsequently remove the carrier wafer 9, the first memory-die backside dielectric layer 106 may be subsequently employed as a polishing stopper material layer. If an etch process such as a wet etch process is employed to subsequently remove the carrier wafer 9, the first memory-die backside dielectric layer 106 may be subsequently employed as an etch stop material layer. In one embodiment, the first memory-die backside dielectric layer 106 comprises a dielectric material such as undoped silicate glass, a doped silicate glass, or silicon nitride. The thickness of the first memory-die backside dielectric layer 106 may be in a range from 50 nm to 600 nm, such as from 100 nm to 300 nm, although lesser and greater thicknesses may also be employed.

In-process source-level material layers 110′ can be formed over the first memory-die backside dielectric layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selectively to the lower sacrificial liner (or selectively to the lower source-level semiconductor layer 112) and the upper sacrificial liner (or selectively to the upper source-level semiconductor layer 116). In one embodiment, the source-level sacrificial layer 104 may include a semiconductor material such as undoped amorphous silicon or a silicon-germanium alloy with an atomic concentration of germanium greater than 20 %. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the first memory-die backside dielectric layer 106 may be omitted, and the alternating stack is formed directly on a surface of the carrier wafer 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier wafer 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The exemplary memory die comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

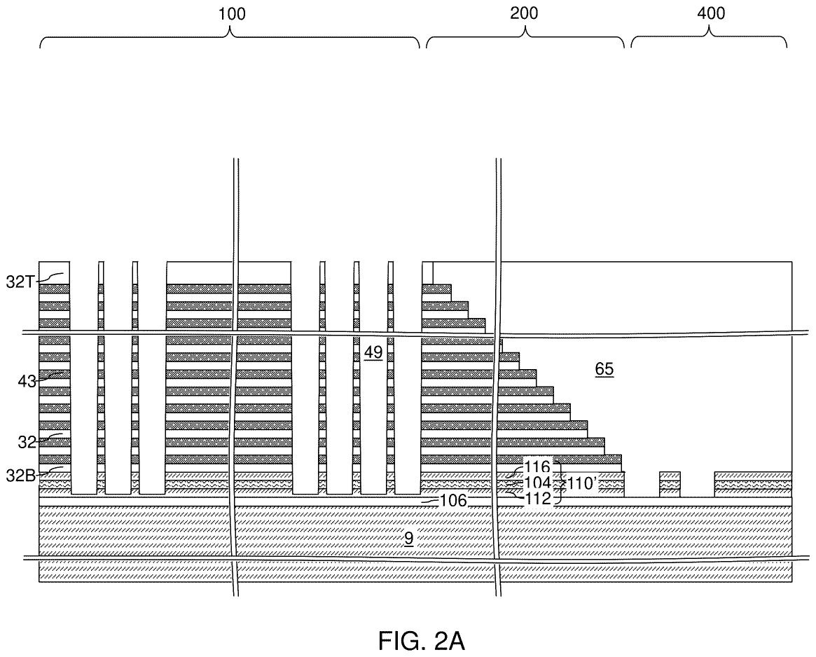

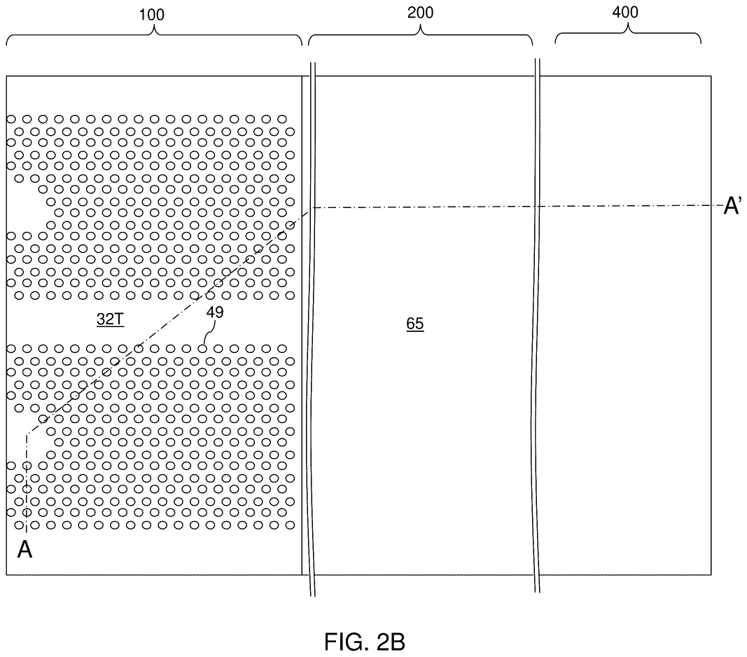

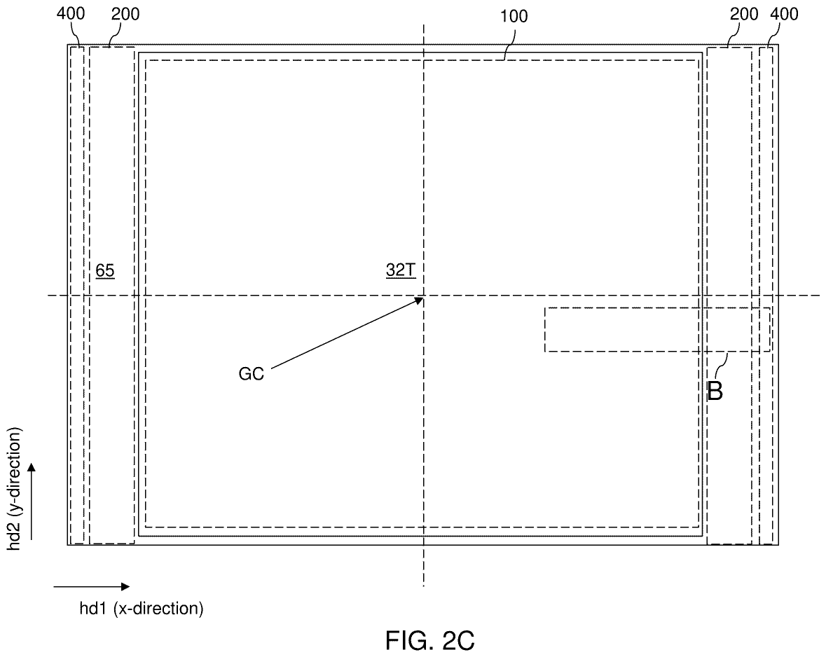

Referring to FIG. 2A-2C, various views of the exemplary memory die are illustrated after formation of memory openings 49. FIG. 2C is a top-down view of the exemplary memory die that illustrates an entire area of a memory die. FIG. 2B is a top-down view of region B of the top-down view of the exemplary memory die shown in FIG. 2C. FIG. 2A is a vertical cross-sectional view of the exemplary memory die along the vertical plane A-A′ of FIG. 2B. The memory die may have a rectangular shape in a plan view, such as the top-down view of FIG. 2C. The geometrical center GC of the memory die is also illustrated in FIG. 2C. As used herein, a geometrical center of an element refers to a center of gravity of a hypothetical object occupying the same volume as the element and having a uniform density throughout.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′. In one embodiment, bottom surfaces of the memory openings 49 and the support openings may be formed within the lower source-level semiconductor layer 112 or at an interface between the lower source-level semiconductor layer and the first memory-die backside dielectric layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd1. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or a polymer material. A dielectric fill material can be deposited in the support openings to form support pillar structures (not shown). The sacrificial memory opening fill structures can be subsequently removed to form cavities in the memory openings 49.

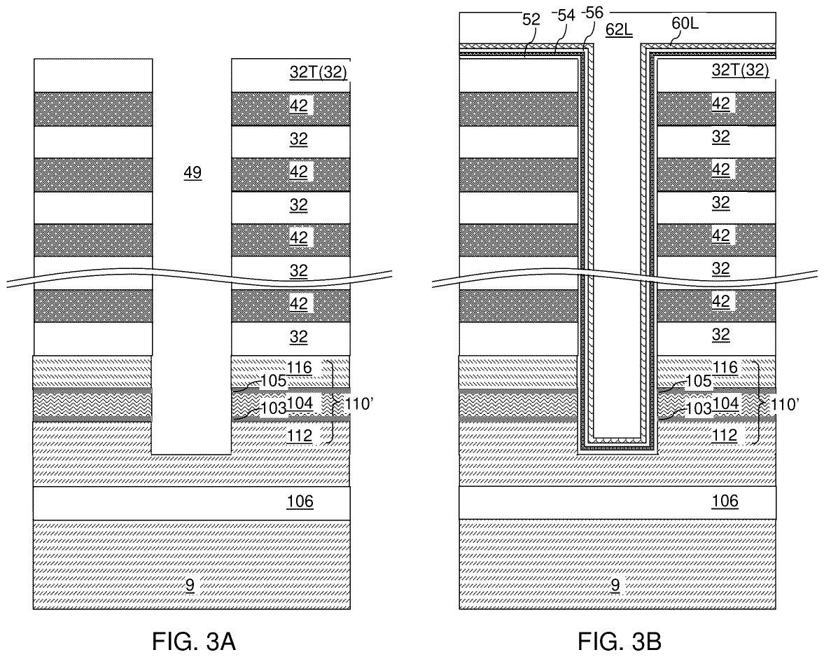

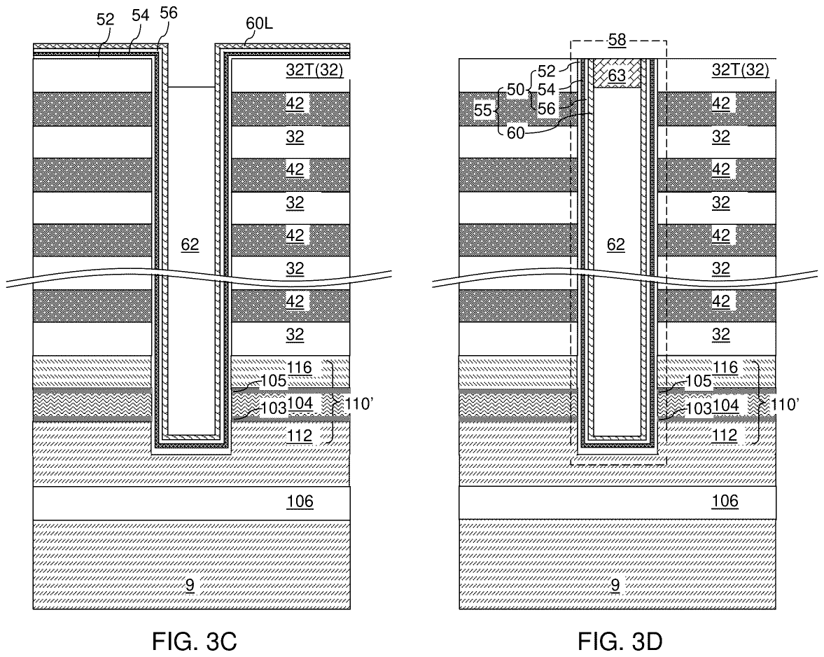

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C .

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprises a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as from 1.0×10¹⁴/cm³ to 3.0×10¹⁶/cm³, although lesser or greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

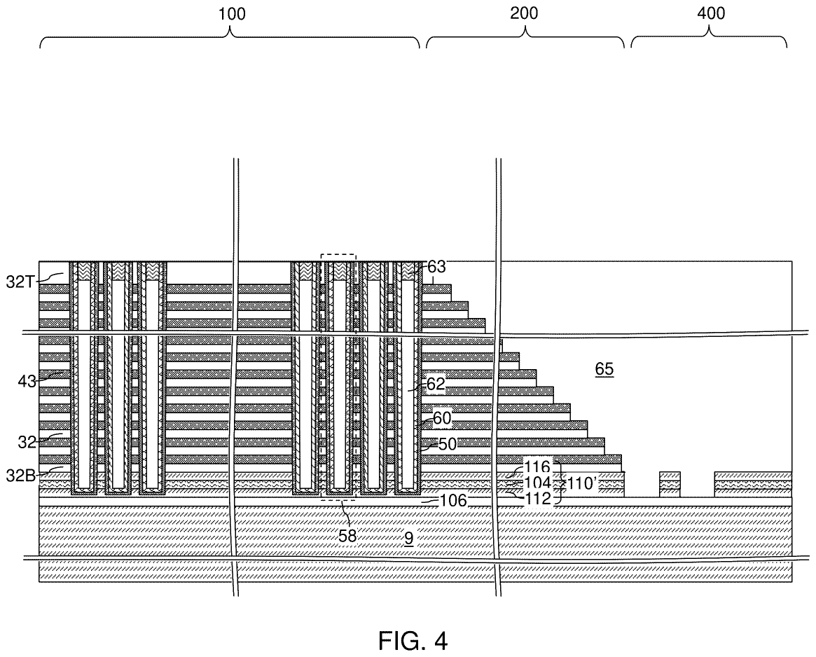

Referring to FIG. 4, the exemplary memory die is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

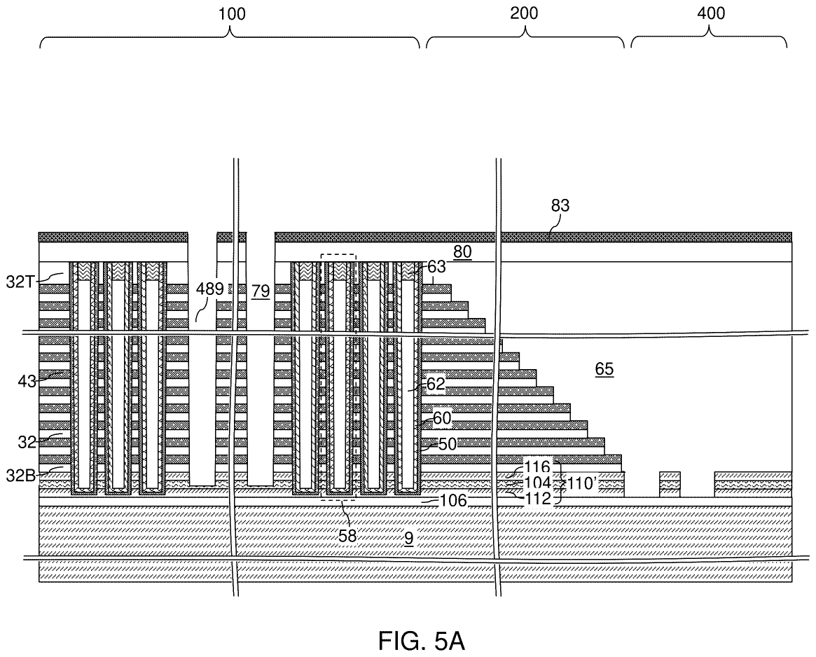

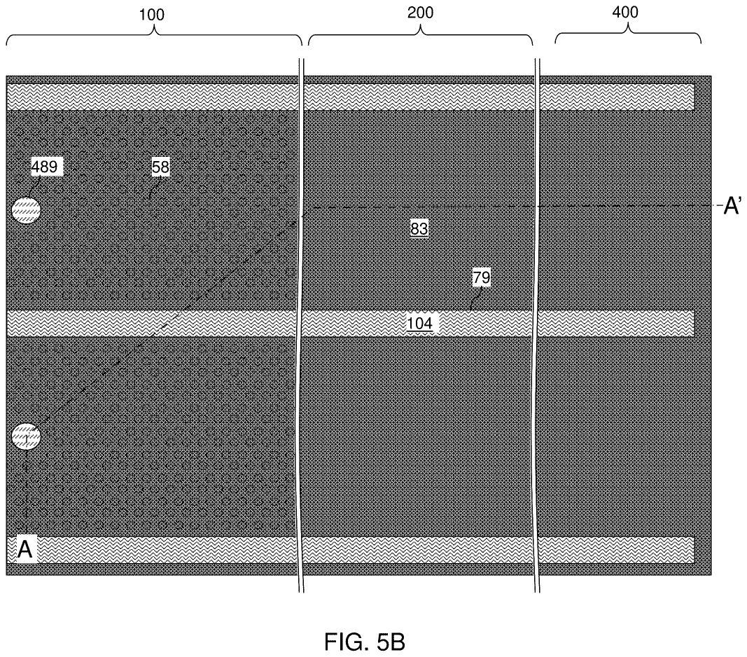

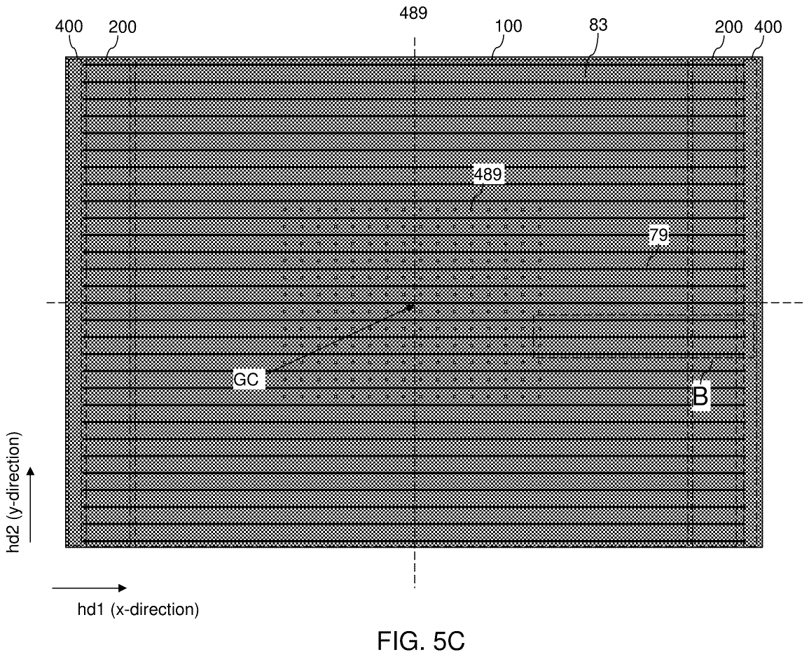

Referring to FIGS. 5A-5C , various views of the exemplary are illustrated after formation of a contact-level dielectric layer 80, a patterned hard mask layer 83, lateral isolation trenches 79, and through-stack openings 489. FIG. 5C is a top-down view of the exemplary memory die that illustrates an entire area of a memory die. FIG. 5B is a top-down view of region B of the top-down view of the exemplary memory die shown in FIG. 5C. FIG. 5A is a vertical cross-sectional view of the exemplary memory die along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 489 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 489 may comprise surface segments of the source-level sacrificial layer 104. In one embodiment, the through-stack openings 489 may be arranged as a two-dimensional periodic array. In one embodiment, the through-stack openings 489 may be formed in a center region of the memory die in a plan view. In one embodiment, peripheral regions of the memory die may be free of any through-stack openings 489.

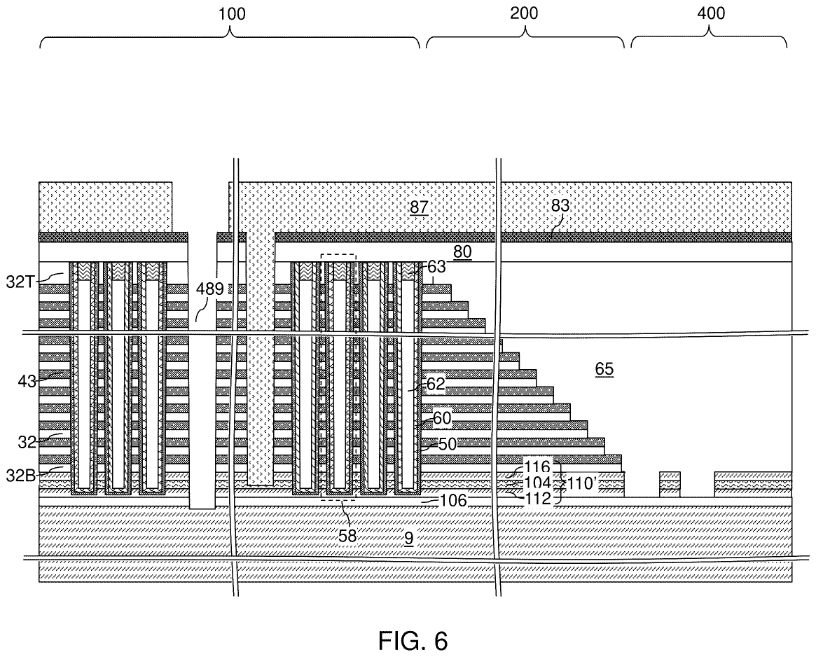

Referring to FIG. 6, a photoresist layer 87 can be applied over the exemplary memory die, and can be lithographically patterned to form openings around the through-stack openings 489. The photoresist layer 87 can cover all areas of the lateral isolation trenches 79. An anisotropic etch process can be performed to vertically extend the through-stack openings 489 through the in-process source-level material layers 110′ and the first memory-die backside dielectric layer 106 and optionally into an upper portion of the carrier wafer 9. The photoresist layer 87 can be subsequently removed, for example, by ashing. The patterned hard mask layer 83 can be removed selectively to the contact-level dielectric layer, for example, by performing a wet etch process.

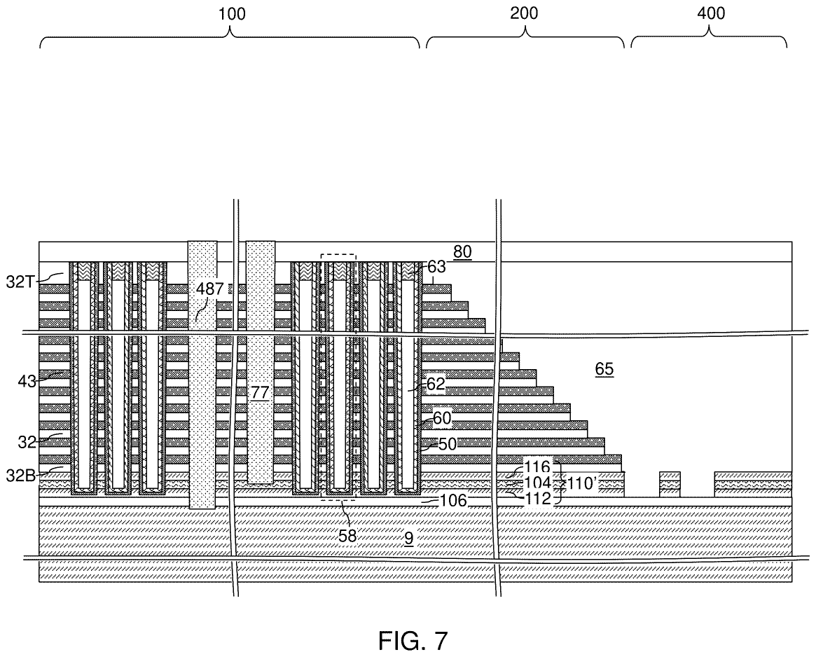

Referring to FIG. 7, a sacrificial fill material can be deposited in the lateral isolation trenches 79 and the through-stack openings 489. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 489 constitute sacrificial through-stack opening fill structures 487.

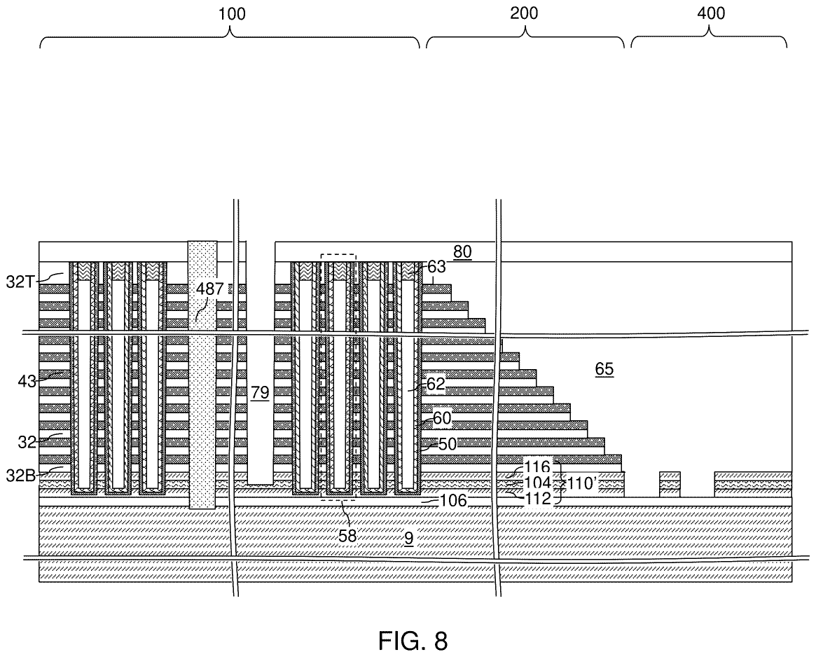

Referring to FIG. 8, a photoresist layer (not shown) can be applied over the contact-level dielectric layer 80, and can be lithographically patterned to cover the sacrificial through-stack opening fill structures 487 without covering the sacrificial lateral isolation trench fill structures 77. The sacrificial lateral isolation trench fill structures 77 can be removed selectively to the materials of the contact-level dielectric layer 80 and the alternating stack (32, 42) to form cavities within the volumes of the lateral isolation trenches 79 (i.e., to reopen the lateral isolation trenches 79).

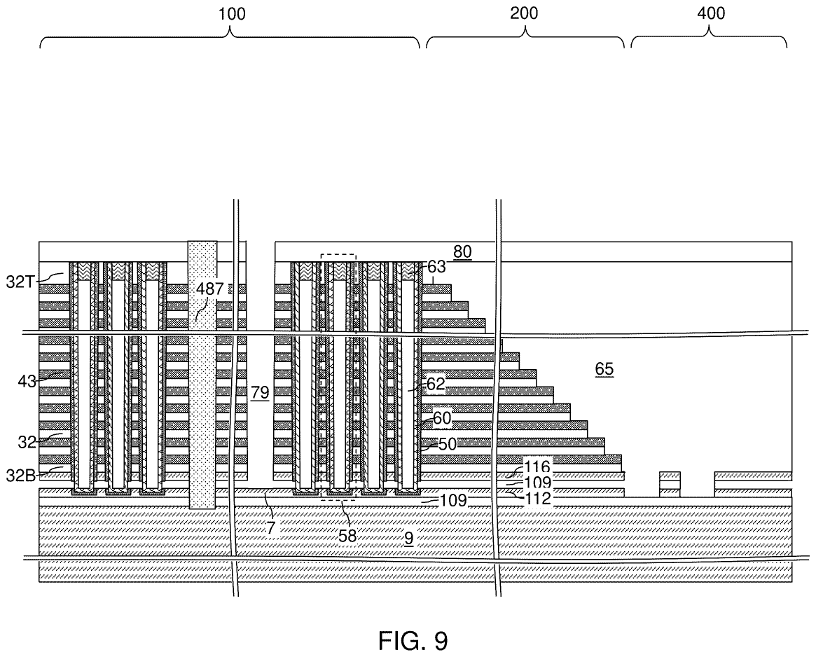

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selectively to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selectively to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary memory die caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selectively to at least one source-level semiconductor layer (such as the lower source-level semiconductor layer 112 and the upper source-level semiconductor layer 116) and the vertical semiconductor channels 60.

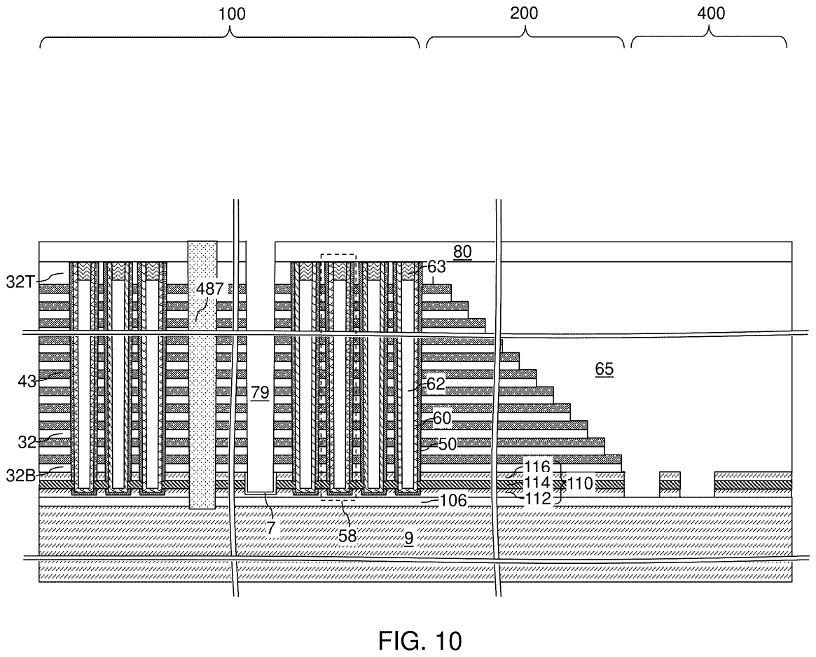

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source layer 110, which replaces the in-process source-level material layers 110′. The source layer 110 contacts a sidewall surface segment of each of the vertical semiconductor channels 60. An oxidation process can be performed to convert physically exposed portions of the semiconductor material layer around bottom portions of the lateral isolation trenches 79. A semiconductor oxide liner 7, such as a silicon oxide liner, can be formed at the bottom of each lateral isolation trench 79.

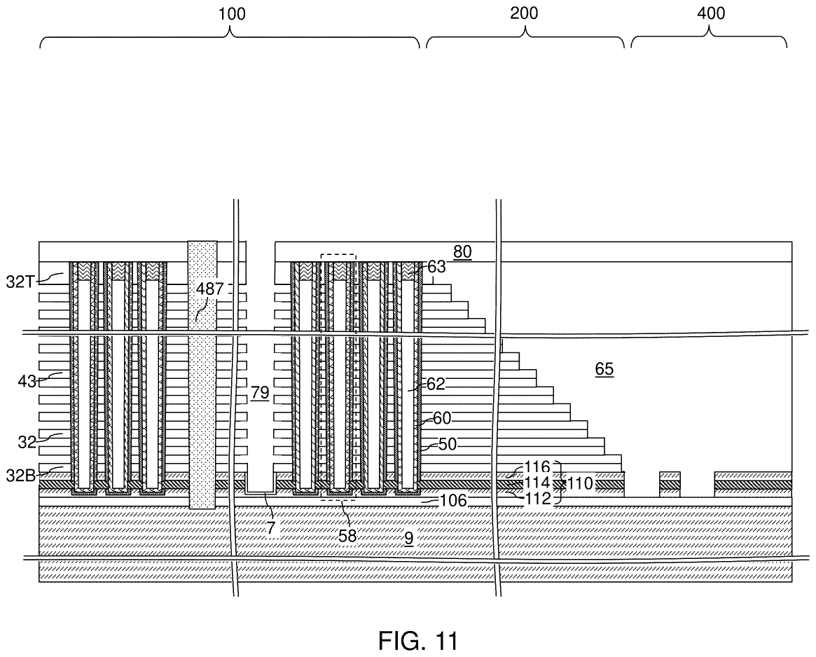

Referring to FIG. 11, an isotropic etch process can be performed to remove the sacrificial material layers 42 selectively to the insulating layers 32, the semiconductor oxide liners 7, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary memory die is immersed in phosphoric acid at or near the boiling point of the phosphoric acid. A suitable clean process may be performed as needed. In summary, the laterally-extending cavities 43 can be formed by removing the sacrificial material layers 42 selectively to the insulating layers 32 and the memory opening fill structures 58.

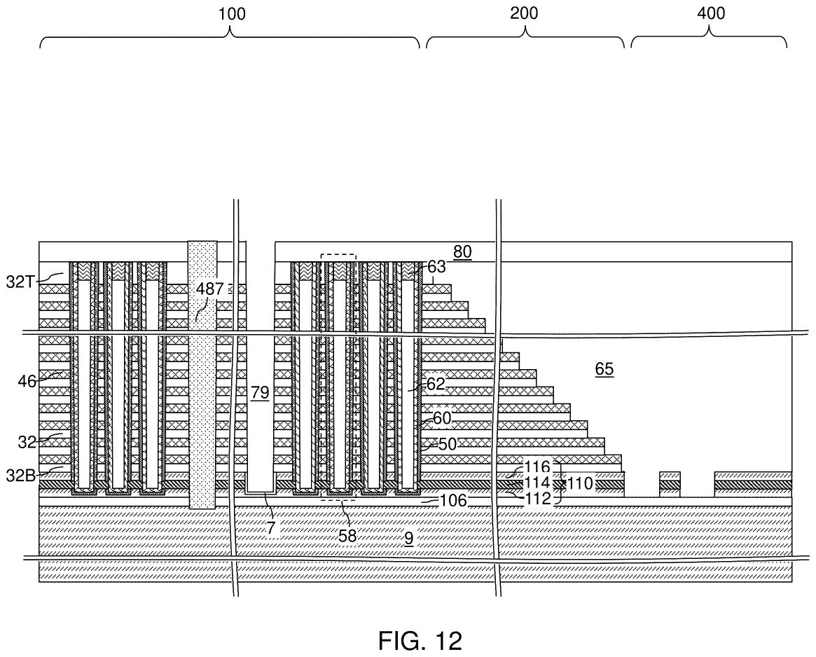

Referring to FIG. 12, a backside blocking dielectric layer (not shown) may be optionally deposited in the laterally-extending cavities 43. The backside blocking dielectric layer, if employed, includes, and/or consists essentially of, a dielectric metal oxide material. At least one metallic material can be conformally deposited in the laterally-extending cavities 43. The at least one metallic material may comprise a combination of a metallic nitride barrier material and a metallic fill material. For example, the metallic nitride barrier material may comprise TiN, TaN, WN, or MoN, and the metallic fill material may comprise W, Ru, Mo, Co, etc.

An anisotropic etch process can be performed to remove portions of the at least one metallic material and optionally the backside blocking dielectric layer from inside the volumes of the lateral isolation trenches 79 and from above the contact-level dielectric layer 80. Each contiguous remaining portion of the at least one metallic material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

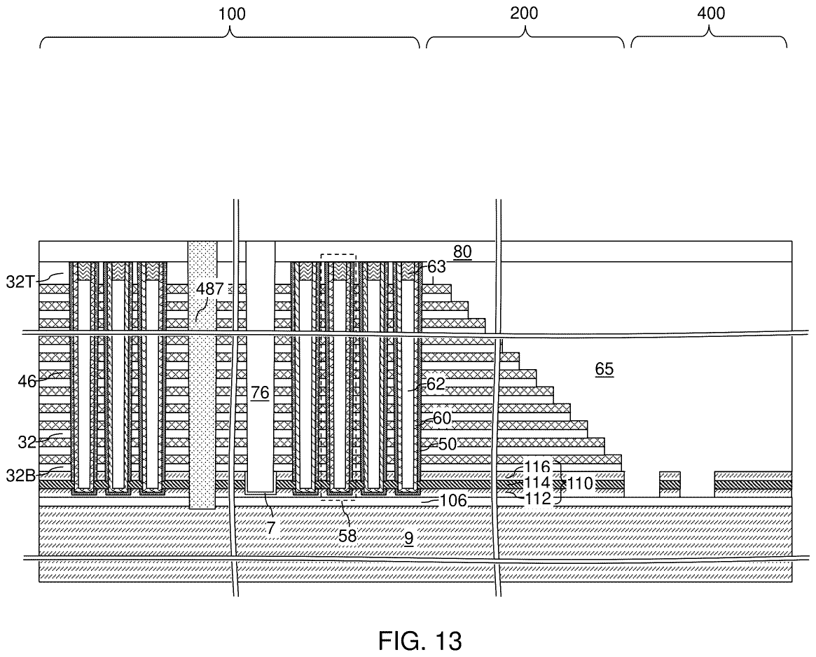

Referring to FIG. 13, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to another horizontal plane including a topmost surface of the alternating stack (32, 46).

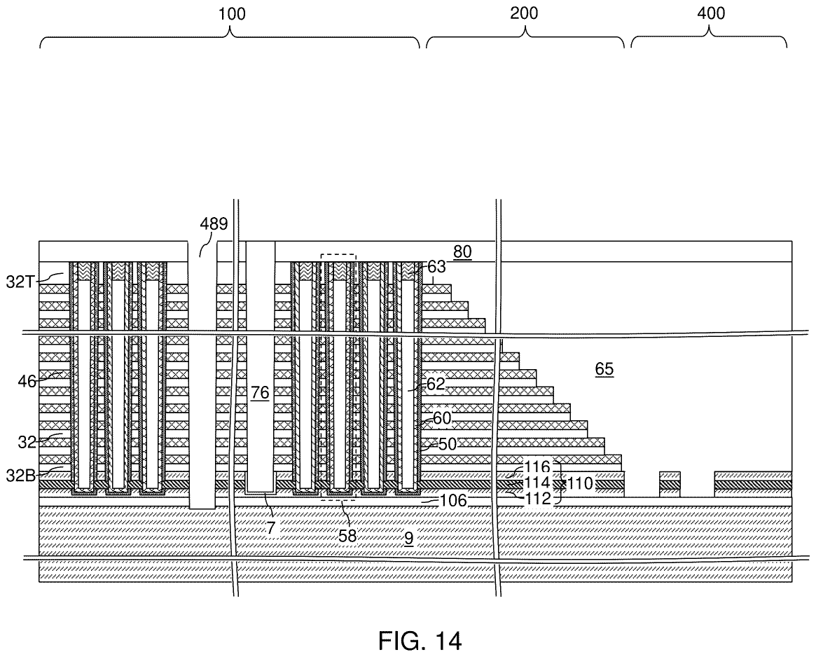

Referring to FIG. 14, a selective etch process can be performed to remove the sacrificial through-stack opening fill structures 487 selectively to the materials of the contact-level dielectric layer 80 and the alternating stacks (32, 42). Cavities are formed in the volumes of the through-stack openings 489.

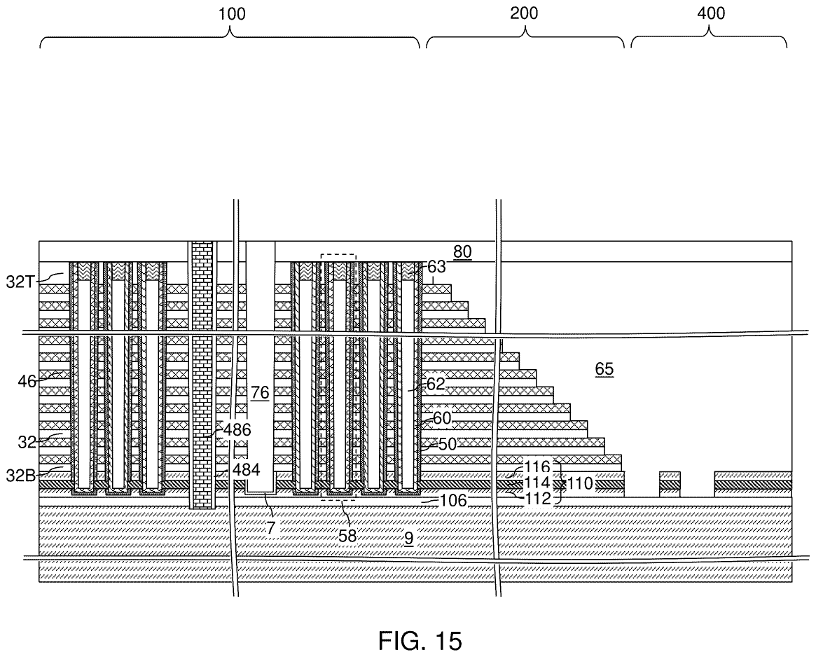

Referring to FIG. 15, a dielectric material, such as silicon oxide, can be conformally deposited in peripheral portions of the through-stack openings 489. An anisotropic etch process can be performed to remove horizontally-extending portions of the deposited dielectric material. Each remaining tubular portion of the deposited dielectric material located in peripheral regions of the through-stack openings 489 constitutes a tubular dielectric spacer 484. The lateral thickness of each tubular dielectric spacer 484 (as measured between an inner sidewall and an outer sidewall) may be in a range from 30 nm to 100 nm, although lesser and greater thicknesses may also be employed.

At least one conductive material, such as at least one metallic material, can be deposited in center regions of the through-stack openings 489. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 489 comprises a through-stack via structure 486.

The through-stack via structures 486 are formed in a center region of the memory die. As used herein, the center region is defined as a volume within the memory die that is more proximal to the geometrical center GC of the memory die than to a periphery of the memory die. The periphery is defined by the outer boundary of the memory die in a plan view along a vertical direction.

In one embodiment, at least one of the vertically-extending openings 489 in the alternating stacks (32, 46) is entirely laterally surrounded by a respective one of the alternating stacks (32, 46). In one embodiment, the entirety of at least one of the vertically-extending openings 489 may be located within the area of a respective one of the alternating stacks (32, 46) in the plan view. In one embodiment, at least one of the through-stack via structures 486 is located within a respective one of the vertically-extending openings 489, and is laterally spaced from a sidewall of the respective one of the vertically-extending opening 489 by a respective tubular dielectric spacer 484.

In one embodiment, sidewalls of the through-stack openings 489 may be tapered such that each through-stack opening 489 has a greater lateral dimension at its top than at its bottom. In one embodiment, sidewalls of the through-stack via structures 486 are tapered relative to a vertical direction such that each of the through-stack via structures 486 has a respective variable horizontal cross-sectional area that increases with a vertical distance from the carrier wafer 9.

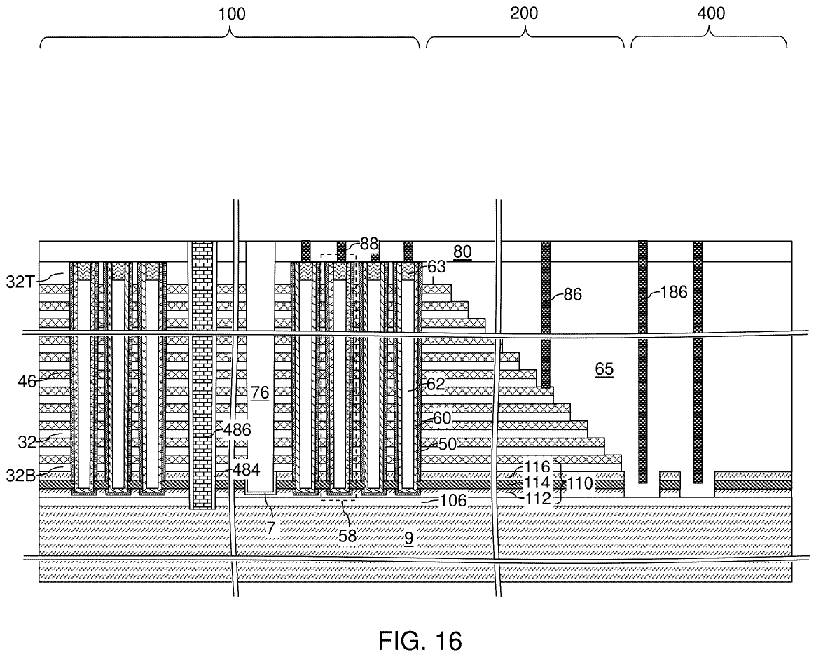

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities constitute peripheral connection via structures 186.

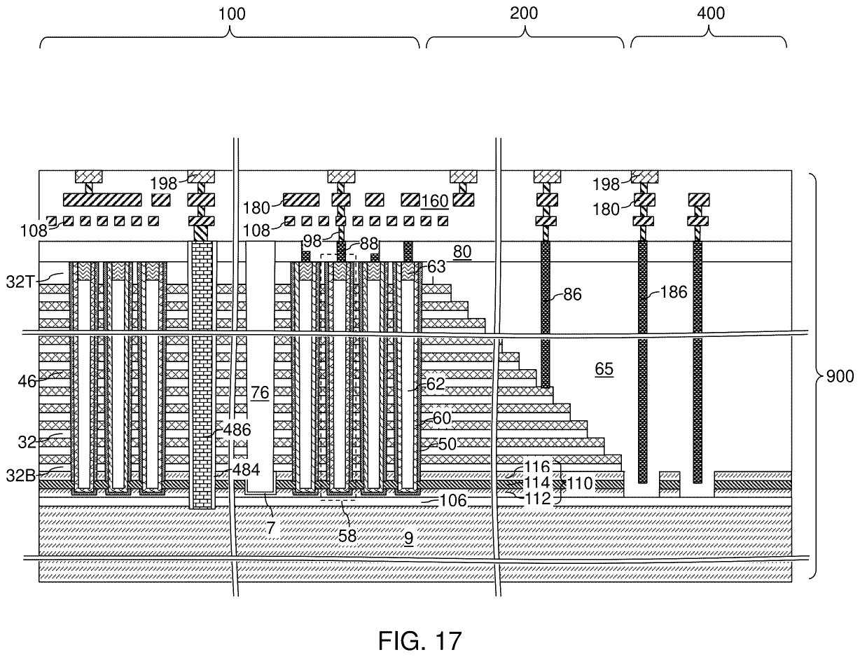

Referring to FIG. 17, additional dielectric material layers embedding metal interconnect structures can be formed over the contact-level dielectric layer 80. The additional dielectric material layers are herein referred to as memory-die front dielectric material layers 160. The metal interconnect structures are herein referred to as memory-die metal interconnect structures (98, 108, 180). The memory-die metal interconnect structures (98, 108, 180) may include bit lines 108 that laterally extend along the second horizontal direction hd2, bit-line-connection via structures 98 that connect the drain contact via structures 88 with the bit lines 108, and additional metal interconnect structures 180 which include various types of metal via structures and various types of metal lines.

Memory-die intra-assembly bonding pads 198 configured for metal-to-metal bonding can be formed in the topmost dielectric layer of the memory-die front dielectric material layers 160. The memory-die intra-assembly bonding pads 198 are subsequently employed to bond with logic-die intra-assembly bonding pads of a logic die so that the combination of the memory die and the logic die becomes a unit bonded assembly in a subsequent processing step. Metal-to-metal bonding involves direct attachment of contacting metal surfaces to each other without use of any intermediate material. As used herein, “metal-to-metal bonding” refers to the process of directly joining metal surfaces without any intervening adhesive or bonding layer. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-die intra-assembly bonding pads 198 may have physically exposed copper surfaces.

The exemplary memory die formation is completed to form a memory die 900, i.e., the final device structure derived from the exemplary memory die. In one embodiment, a two-dimensional array of memory dies 900 may be formed on the same carrier wafer 9. For example, the carrier wafer 9 may comprise a commercially available silicon wafer, and the two-dimensional array of memory dies 900 may comprise a periodic rectangular array of memory dies 900 comprising a respective portion of the silicon wafer and the overlying device layers.

In one embodiment, a plurality of memory wafers (i.e., carrier wafers 9) can be provided. Within each memory wafer, each of the plurality of memory dies 900 may comprise: an alternating stack (32, 46) of insulating layers 32 and electrically conductive layers 46 that alternate along a vertical direction; a two-dimensional array of memory stack structures 55 each containing a respective vertical semiconductor channel 60 and respective vertical stack of memory elements (comprising portions of the memory material layer 54); and through-stack via structures 486 vertically extending at least from a horizontal plane including a bottommost surface of the alternating stack (32, 46) to another horizontal plane including a topmost surface of the alternating stack (32, 46).

Each memory die 900 also includes set of memory-die metal interconnect structures 980 embedded within a set of memory-die dielectric material layers 960, memory-die intra-assembly bonding pads 198, and memory-die inter-assembly bonding pads 128. Further, each memory die 900 includes a source layer 110 in contact with end portions of vertical semiconductor channels within the memory stack structures 55 and at least one source connection structure 122 in contact with a backside surface of the source layer 110.

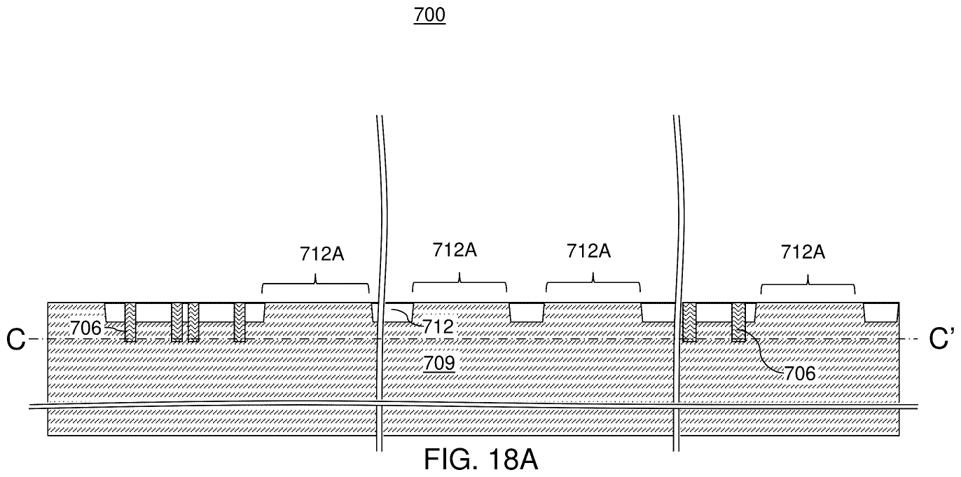

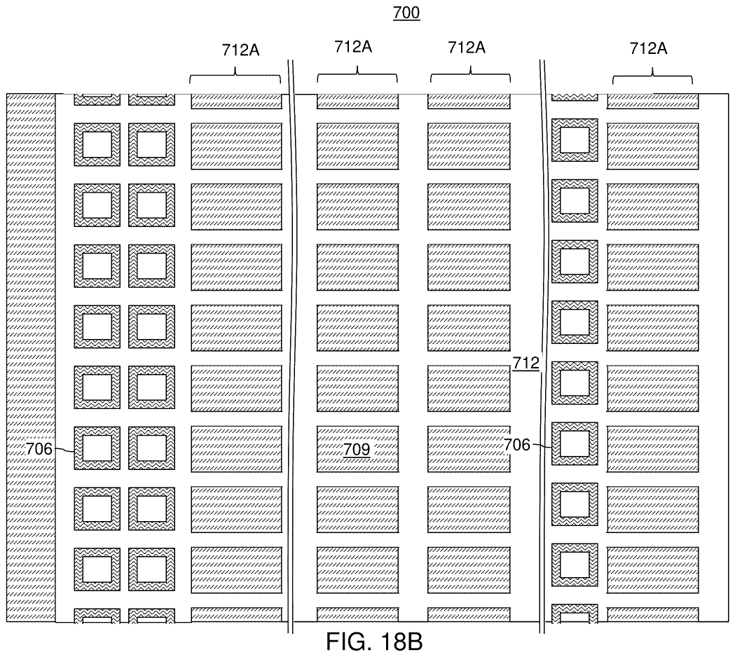

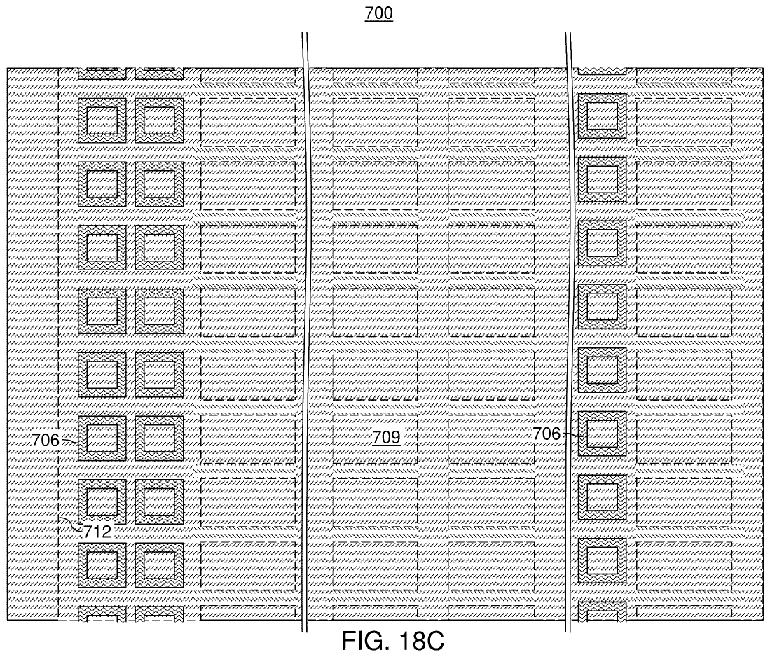

Referring to FIG. 18A-18C, an exemplary logic die 700 is illustrated. The exemplary logic die 700 may be provided within a unit area on a substrate, such as a semiconductor (e.g., silicon) wafer including a two-dimensional array of logic dies 700. The exemplary logic die comprises a substrate, such as a substrate semiconductor layer 709, which is also referred to as a logic-die substrate. The substrate semiconductor layer 709 may comprise a semiconductor wafer.

According to an aspect of the present disclosure, a commercially available semiconductor wafer 709, such as a silicon wafer having a diameter in a range from 100 mm to 450 mm may be employed to form the exemplary logic die. The semiconductor wafer may have the same area as the carrier wafer 9 (i.e., the memory wafer). A plurality of logic dies 700, such as a two-dimensional array of logic dies, can be formed on the semiconductor wafer 709. In this case, the exemplary logic die 700 may be one of the logic dies that are formed on the semiconductor wafer 700, and a two-dimensional array of the exemplary logic dies described below may be formed over the semiconductor wafer 709. The semiconductor wafer (i.e., the substrate semiconductor layer) 709 including a two-dimensional array of logic dies is referred to as a logic wafer. Thus, it should be understood that the structural features for the exemplary logic die described herein may be formed on all or part of the logic dies on the semiconductor wafer 709 at the same time.

The substrate semiconductor layer 709 comprises a substrate semiconductor material, which may be a single crystalline semiconductor material, such as single crystalline silicon. The substrate semiconductor layer 709 may have a doping of a first or second conductivity type, such as p-type or n-type. The atomic concentration of dopants of the first conductivity type in the substrate semiconductor layer 709 may be in a range from 1.0×10¹³/cm³ to 3.0×10¹⁷/cm³, although lesser or greater atomic concentrations may also be employed.

An ion implantation mask layer (such as a photoresist layer) can be applied over the top surface of the substrate semiconductor layer 709, and can be lithographically patterned to form annular openings around areas in which through-substrate via structures are to be formed in subsequent processing steps. In one embodiment, the annular openings may be formed as arrays of frame-shaped openings and/or as arrays of annular openings in the plan view.

An ion implantation process can be performed to implant dopants through the openings in the ion implantation mask layer into underlying portions of the substrate semiconductor layer 709. The dopants may have a higher concentration and the same or opposite conductivity type relative to the dopants of the substrate semiconductor layer 709. For example, the dopants may comprise p-type dopants. However, n-type dopants may be used in an alternative embodiment. Doped semiconductor wells 706 are formed in surface portions of the substrate semiconductor layer 709. The horizontal cross-sectional shapes of the doped semiconductor wells 706 may comprise frame shapes and/or annular shapes. The atomic concentration of the dopants in the doped semiconductor wells 706 may be in a range from 1.0×10¹⁸/cm³ to 2.0×10²¹/cm³, although lesser and greater atomic concentrations may also be employed. The vertical extent of the doped semiconductor wells 706, as measured between the top surface and the bottom surface, may be in a range from 500 nm to 2,000 nm, such as from 700 nm to 1,500 nm, although lesser or greater vertical extent may also be employed. A p-n junction can be formed at each interface between the doped semiconductor wells 706 and the substrate semiconductor layer 709. The ion implantation mask layer may be subsequently removed.

Shallow trench isolation structures 712 can be formed on the front side of the substrate semiconductor layer 709 around the doped semiconductor wells 706. Specifically, shallow trenches can be formed on the front side of the substrate semiconductor layer 709 by locally recessing surface regions of the substrate semiconductor layer in which semiconductor devices are not to be formed (such as boundaries between neighboring pairs of semiconductor devices), by filling the shallow trenches with a dielectric fill material, such as silicon oxide, and by removing excess portions of the dielectric fill material from above the horizontal plane including the unrecessed top surface of the substrate semiconductor layer 709. The areas of the shallow trenches do not overlap with the doped semiconductor wells 706. In one embodiment, each of the doped semiconductor wells 706 may have a respective annular shape, and the shallow trenches can be formed inside the inner periphery of each doped semiconductor well 706 and outside the outer periphery of each doped semiconductor well 706. In some embodiments, each doped semiconductor well 706 may comprise a respective inner sidewall segment that is exposed to a respective inner shallow isolation trench, and a respective outer sidewall segment that is exposed to a respective outer shallow isolation trench. The remaining portions of the dielectric fill material filling the shallow trenches constitute the shallow trench isolation structures 712. Thus, shallow trench isolation structures 712 can be formed in an upper portion of the substrate semiconductor layer 709 over the doped semiconductor wells 706. The vertical extent (i.e., thickness) of the shallow trench isolation structures 712 may be in a range from 200 nm to 600 nm, although lesser or greater vertical extents may also be employed. In one embodiment, the shallow trench isolation structures 712 contain discrete openings 712A therein in a plan view. The areas of the discrete openings 712A correspond to device areas in which semiconductor devices for a memory controller circuit are to be subsequently formed. In one embodiment, the shallow trench isolation structures 712 may comprise an array of openings 712A such as an array of rectangular openings in the plan view, as shown in FIG. 18A. Each doped semiconductor wells 706 may laterally surround a respective shallow trench isolation structure 712, and may be laterally surrounded by a respective shallow trench isolation structure 712.

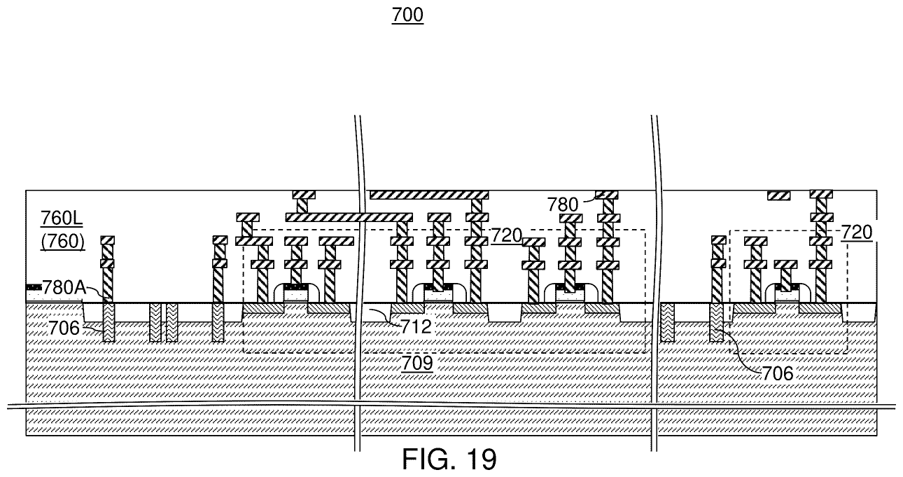

Referring to FIG. 19, a memory controller circuit 720, which is also referred to as a peripheral circuit or driver circuit, can be formed on and/or over the top surface of the substrate semiconductor layer 709. The memory controller circuit 720 is configured to control operation of the memory array within a memory die 900. For example, the memory controller circuit 720 may comprise word line drivers configured to drive word lines, which are a subset of the electrically conductive layers 46 within the alternating stacks (32, 46). The memory controller circuit 720 may comprise bit line drivers configured to drive the bit lines 108 in the memory die 900. For example, as described with reference to the memory die 900, the bit lines 108 of a memory die 900 may be electrically connected to first ends (i.e., the ends that are connected to the drain regions 63) of a respective subset of the memory stack structures 55. The memory controller circuit 720 may comprise source line drivers configured to drive one or more source layers to be subsequently formed on the memory die 900 after removal of the carrier wafer 9. The memory controller circuit 720 may also comprise input/output control circuits configured to receive input data from, or to transmit output data to, at least one conductive pad (which may be a bonding structure) to be subsequently formed on the through-stack via structures 486 after removal of the carrier wafer 9. Generally, the memory controller circuit 720 may comprise any electronic circuit configured to manage data flow, handle read and write operations, ensure data integrity through error correction, perform wear leveling to extend memory lifespan, and/or support communication protocols for interfacing with external devices and systems for the three-dimensional memory array in the memory die 900.

Specifically, a first subset of logic-die metal interconnect structures 780 embedded within a first subset of logic-die dielectric material layers 760 can be formed over the memory controller circuit 720 and the substrate semiconductor layer 709. The first subset of the logic-die dielectric material layers 760 is herein referred to as lower logic-die dielectric material layers 760L. In the illustrated example in FIG. 19, the lower logic-die dielectric material layers 760L comprise four via-level dielectric material layers and four line-level dielectric material layers. Generally, the total number of line levels within the lower logic-die dielectric material layers 760L may be in a range from 1 to 12. The first subset of the logic-die metal interconnect structures 780 is herein referred to as lower logic-die metal interconnect structures, and comprise metal line structures and metal via structures.

According to an aspect of the present disclosure, a subset of the logic-die metal interconnect structures 780 comprises ground connection metal via structures and metal line structures 780A configured to electrically bias the doped semiconductor wells 706. The ground connection metal via structures and the metal line structures 780A may electrically connect the doped semiconductor wells 706 to electrical ground of the logic die 700. The electrical ground of the logic die may comprise a set of metal interconnect structures that is subsequently electrically connected to the electrical ground of a bonded assembly including a plurality of memory dies and the logic dies and optionally at least one external controller die. In one embodiment, the electrical ground of the logic die may be connected to a subset of the memory controller circuits 720.

In one embodiment, each of the doped semiconductor wells 706 may be contacted by a respective ground connection metal via structure 780A that vertically extends through an overlying shallow trench isolation structure 712. In an alternative embodiment, at least the upper portions of the doped semiconductor wells 706 may be formed by epitaxially growing a doped semiconductor material (e.g., doped single crystal silicon) through openings in the shallow trench isolation structures 712 which expose a horizontal surface of the substrate semiconductor layer 706.

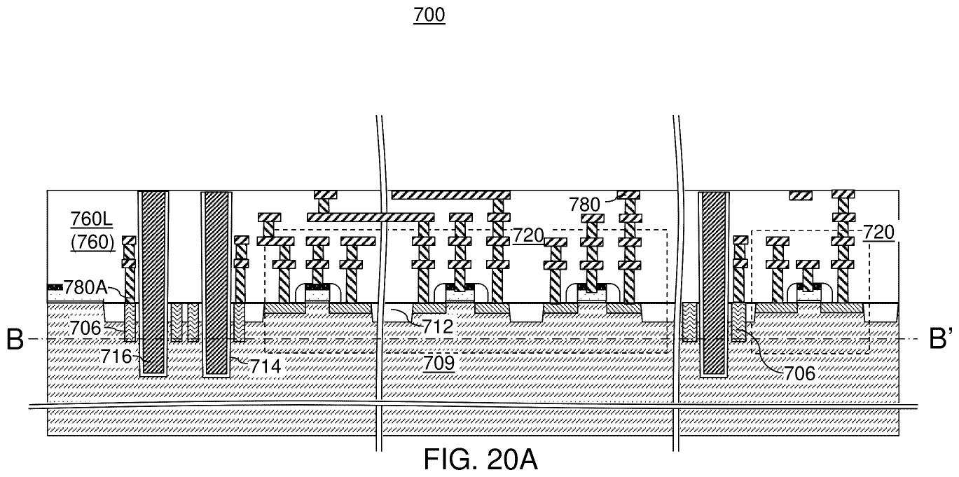

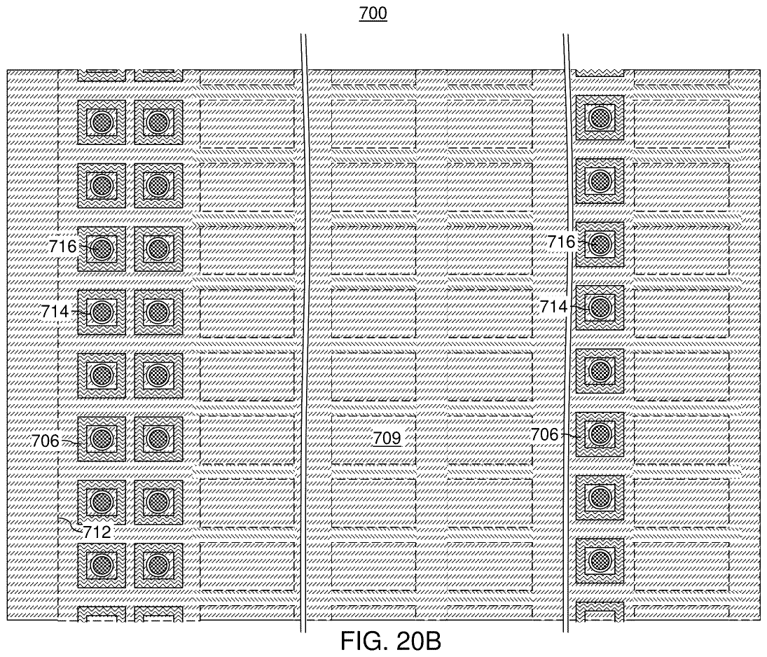

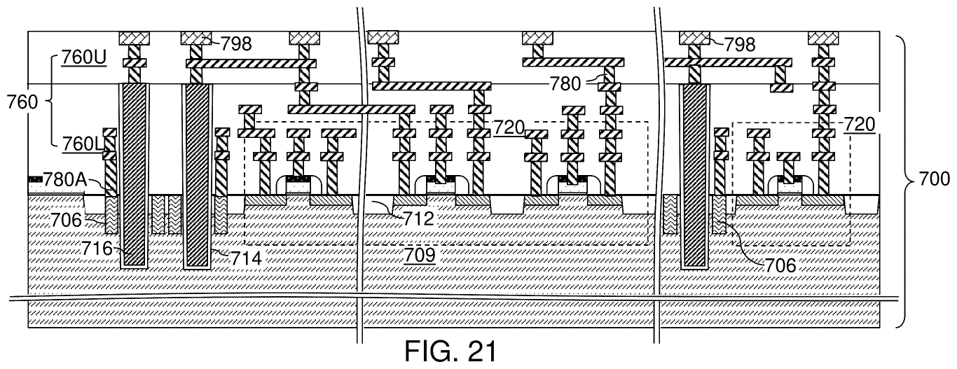

Referring to FIGS. 20A and 20B, vertically-extending cavities may be formed through the lower logic-die dielectric material layers 760L and into an upper portion of the substrate semiconductor layer 709. For example, a photoresist layer (not shown) may be applied over the top surface of the lower logic-die dielectric material layers 760L, and may be lithographically patterned to form discrete openings. In one embodiment, each discrete opening may be formed entirely within an area of an inner sidewall of a respective one of the doped semiconductor wells 706 in the plan view. An anisotropic etch process can be performed to transfer the pattern of the openings in the photoresist layer through the lower logic-die dielectric material layers 760L and the shallow trench isolation structure 712 and into an upper portion of the substrate semiconductor layer 709. The bottom surfaces of the vertically-extending cavities may be formed below the horizontal plane including the bottom surfaces of the doped semiconductor wells 706. For example, the depth of the bottom surfaces of the vertically-extending cavities, as measured from the horizontal plane including the top surface of the substrate semiconductor layer 709, may be in a range from 1 micron to 20 microns, such as from 2 microns to 10 microns, although greater depths may also be employed. The photoresist layer may be subsequently removed, for example, by ashing.

A dielectric spacer material layer may be conformally deposited in peripheral regions of the vertically-extending cavities. For example, a silicon oxide layer may be conformally deposited by a chemical vapor deposition process. The thickness of the dielectric spacer material layer may be in a range from 30 nm to 600 nm, such as from 60 nm to 300 nm, although lesser or greater thicknesses may also be employed. At least one conductive material may be deposited in the remaining volumes of the vertically-extending cavities. The at least one conductive material may comprise, for example, a combination of a metallic liner material (such as TiN, TaN, WN, and/or MoN) and a metal fill material (such as Cu, W, Ti, Ta, Mo, Co, Ru, etc.). The at least one conductive material may be deposited by chemical vapor deposition, physical vapor deposition, electroplating, and/or electroless plating.

Excess portions of the at least one conductive material and the dielectric spacer material layer may be removed from above the horizontal plane including the top surface of the lower logic-die dielectric material layers 760L by performing a planarization process. The planarization process may comprise a recess etch process and/or a chemical mechanical polishing process. Each remaining portion of the dielectric spacer material layer located in a peripheral region of a respective vertically-extending cavity constitutes a dielectric spacer 714. Each remaining portion of the at least one conductive material located in the central region of a respective vertically-extending cavity constitutes a through-substrate via structure 716. In one embodiment, the through-substrate via structures 716 do not vertically extend through the logic-die substrate (i.e., portion of the substrate semiconductor layer 709) at this processing step. However, the through-substrate via structures 716 vertically extend through the logic-die substrate upon thinning of the logic-die substrate from the backside in subsequent processing steps.

In summary, each logic die 700 comprises a respective logic die substrate that includes a portion of the substrate semiconductor layer 709 and a subset of the shallow trench isolation structures 712 and the doped semiconductor wells 706 embedded therein. At least a subset of the through-substrate via structures 716 may be laterally surrounded by a respective doped semiconductor well 706 which is embedded within the substrate semiconductor layer 709. In one embodiment, each doped semiconductor well 706 has a doping of an opposite conductivity type to that of the substrate semiconductor layer 709, such that a p-n junction is present at the interface between the substrate semiconductor layer 709 and each doped semiconductor well 706.

In one embodiment, each of the through-substrate via structures 716 may be laterally surrounded by a respective doped semiconductor well 706, such that the doped semiconductor wells 706 form guard rings around the through-substrate via structures 716. In one embodiment, each doped semiconductor well 706 is laterally spaced from the respective through-substrate via structures 716 by a respective dielectric spacer 714 and a respective portion of the substrate semiconductor layer 709. In this case, each p-n junction is not in direct contact with any dielectric spacer 714.

Shallow trench isolation structure 712 are located in the top portion of the substrate semiconductor layer 709, and can laterally surround the through-substrate via structures 716. The shallow trench isolation structures 712 laterally contact the doped semiconductor wells 706. In one embodiment, each doped semiconductor well 706 may have a respective frame-shaped top surface or an annular top surface. The bottom surface of each doped semiconductor well 706 can be vertically spaced from the backside surface of the substrate semiconductor layer 709.

In one embodiment, each doped semiconductor well 706 is electrically connected by a ground connection subset 780A of the logic-die metal interconnect structures 780 to the electrically ground of the logic die 700. In one embodiment, each doped semiconductor well 706 is topologically homeomorphic to a torus and not in direct contact with the through-substrate via structures 716. As used herein, an element is “topologically homeomorphic to a torus” if the element can be continuously stretched or shrunk without creating a new hole and without eliminating any pre-existing hole.

Referring to FIG. 21, a second subset of the logic-die metal interconnect structures 780 embedded within a second subset of the logic-die dielectric material layers 760 can be formed. The second subset of the logic-die dielectric material layers 760 is herein referred to as upper logic-die dielectric material layers 760U. In the illustrated example in FIG. 21, the upper logic-die dielectric material layers 760U comprise two via-level dielectric material layers and a line-level dielectric material layer. Generally, the total number of line levels within the upper logic-die dielectric material layers 760U may be in a range from 1 to 12.

Bonding structures configured for metal-to-metal bonding with a memory die can be formed in the topmost layer among the logic-die dielectric material layers 760. These bonding structures are herein referred to as logic-die intra-assembly bonding pads 798. The logic-die intra-assembly bonding pads 798 can be electrically connected to a respective electrical node of the memory controller circuit 720, and can be arranged in a pattern that is a mirror image pattern of the memory-die intra-assembly bonding pads 198 of the memory die 900. In one embodiment, each logic die 700 may be provided within a unit die area in a semiconductor wafer including a two-dimensional array of logic dies 700.

A plurality of logic dies 700 may be provided. Each logic die 700 comprises a respective substrate semiconductor layer 709, a respective memory controller circuit 720 including a respective set of semiconductor devices located on a front surface of the respective substrate semiconductor layer 709; respective logic-die dielectric material layers 760 embedding respective logic-die metal interconnect structures 780 and located on the respective set of semiconductor devices; respective logic-die intra-assembly bonding pads 798 that are embedded within the logic-die dielectric material layers 760; and respective through-substrate via structures 716 that vertically extend through a subset of the respective logic-die dielectric material layers 760 and an upper portion of the respective substrate semiconductor layer 709.

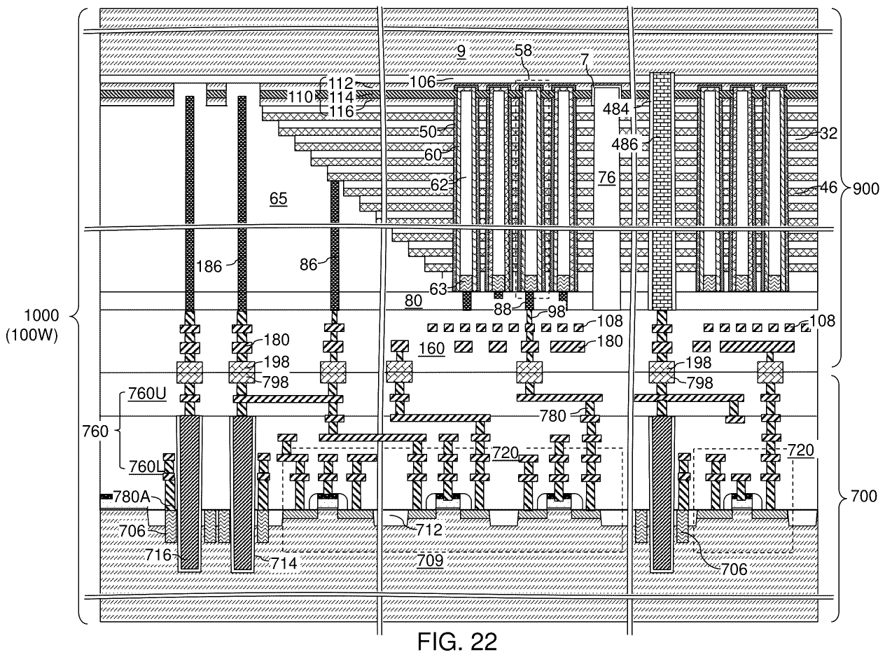

Referring to FIG. 22, a bonded wafer assembly 100W can be formed by bonding the logic dies 700 described with reference to FIG. 21 with the memory dies 900 described with reference to FIG. 17. In one embodiment, a memory wafer 9 supporting a two-dimensional array of memory dies 900 may be bonded to a logic wafer 709 supporting a two-dimensional array of logic dies 700 by performing a wafer-to-wafer bonding process, in which mating pairs of memory-die intra-assembly bonding pads 198 and logic-die intra-assembly bonding pads 798 are bonded via metal-to-metal bonding, such as copper-to-copper bonding. Further, contacting surfaces of the outermost layer of the memory-die dielectric material layers 160 and the outermost layer of the logic-die dielectric material layers 760 may be bonded to each other via dielectric-to-dielectric bonding, such as oxide-to-oxide bonding (in which a silicon oxide layer is bonded to another silicon oxide layer). A plurality of unit bonded assemblies 1000 can be formed within the bonded wafer assembly 100W of the memory wafer and the logic wafer. Within each unit bonded assembly 1000, the logic die 700 can be bonded to the memory die 900 by bonding the logic-die intra-assembly bonding pads 798 to the memory-die intra-assembly bonding pads 198.

In summary, the bonding between mating pairs of a respective memory die 900 and a respective logic die 700 may be performed employing a wafer-to-wafer bonding process in which a two-dimensional array of memory dies 900 is bonded to a two-dimensional array of logic dies 700. Alternatively, the bonding may comprise a die-to-wafer bonding process (in which a diced die is bonded to a wafer), or a die-to-die bonding process (in which two diced dies are bonded to each other).

The memory die 900 comprises alternating stacks (32, 46) of insulating layers 32 and electrically conductive layers 46 and memory-die front dielectric material layers 160 embedding memory-die metal interconnect structures (180, 108, 98) and memory-die intra-assembly bonding pads 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. In one embodiment, through-stack via structures 486 vertically extend through vertically-extending openings 489 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A logic die 700 comprises a memory controller circuit 720 including a control circuitry for controlling operation of the electrically conductive layers 46 and further comprises logic-die dielectric material layers 760 embedding logic-die metal interconnect structures 780 and logic-die intra-assembly bonding pads 798. The logic-die intra-assembly bonding pads 798 are bonded to the memory-die intra-assembly bonding pads 198.

Within each unit area of the bonded wafer assembly 100W including a respective memory die 900 and a respective logic die 700, the respective memory die 900 comprises respective memory-die intra-assembly bonding pads 198 embedded within respective memory-die front dielectric material layers 160, and the respective logic die 700 comprises respective logic-die intra-assembly bonding pads 798 embedded within respective logic-die dielectric material layers 760 and bonded to the respective memory-die intra-assembly bonding pads 198. In one embodiment, the respective logic-die intra-assembly bonding pads 798 are bonded to the respective memory-die intra-assembly bonding pads 198 via metal-to-metal bonding, such as copper-to-copper bonding.

In one embodiment, dielectric-to-dielectric bonding, such as silicon oxide-to-silicon oxide bonding, may be employed in conjunction with the metal-to-metal bonding. In this case, a topmost memory-die front dielectric material layer of the respective memory-die front dielectric material layers 160 is bonded to a topmost logic-die dielectric material layer among the logic-die dielectric material layers 760 via dielectric-to-dielectric bonding (i.e., hybrid bonding is used to bond the respective memory die to the respective logic die).

In one embodiment, the respective memory die 900 includes a respective three-dimensional array of memory elements (which may be embodied as portions of a memory material layer 54), and the respective logic die 700 includes a respective memory controller circuit 720 configured to control operation of the respective three-dimensional array of memory elements. In one embodiment, a subset of the through-stack via structures 486 is electrically connected to a subset of semiconductor devices (e.g., input/output control devices, such as field effect transistors) in the respective memory controller circuit 720 of the logic die 700 through a subset of the memory-die metal interconnect structures (180, 108, 98) and through a subset of the logic-die metal interconnect structures 780.

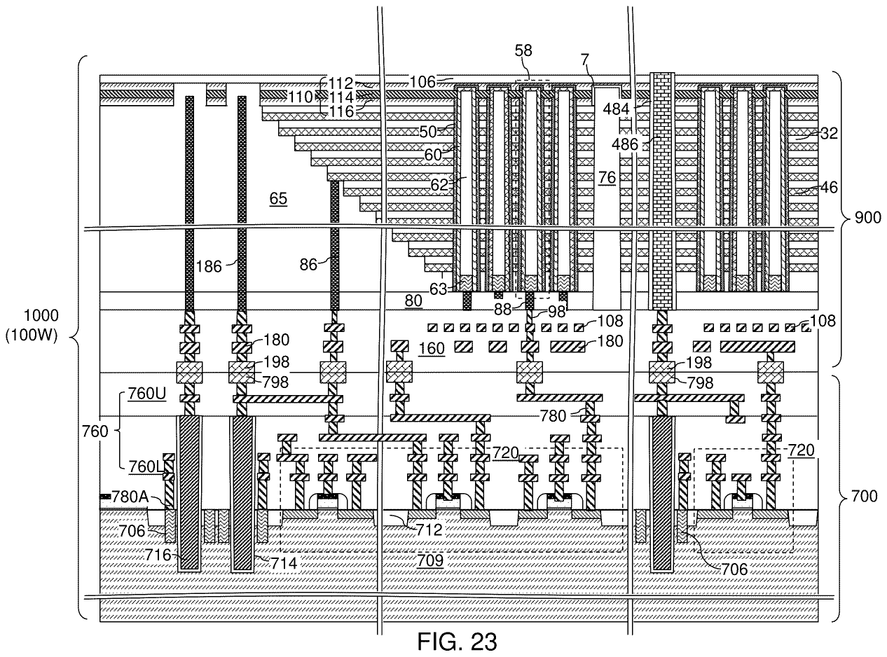

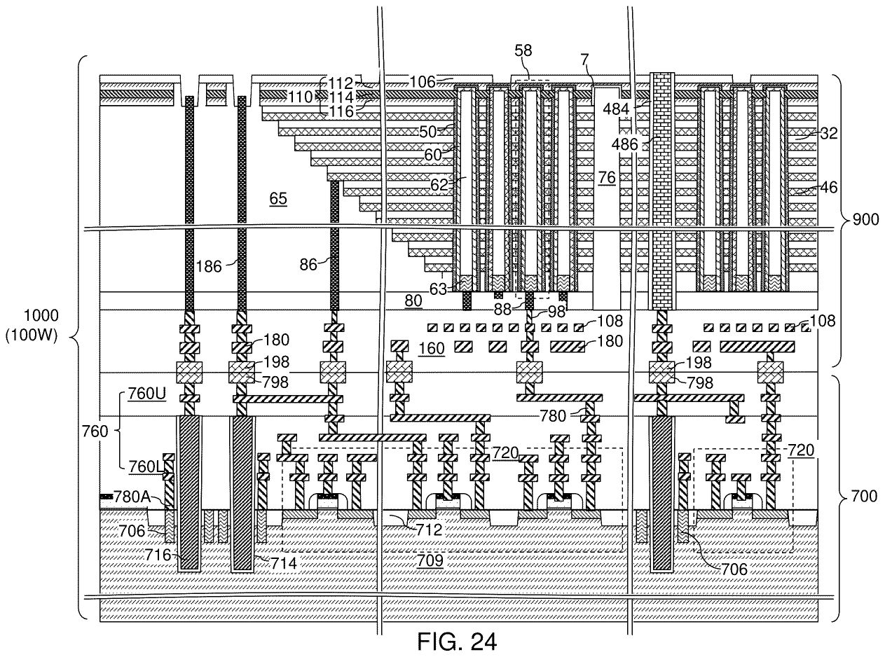

Referring to FIG. 23, the carrier wafer 9 may be removed, for example, by grinding, polishing, cleaving, an isotropic etch process, and/or an anisotropic etch process. If a polishing process such as a chemical mechanical polishing process is employed to remove the carrier wafer 9, the first memory-die backside dielectric layer 106 may be subsequently employed as a polishing stopper material layer. If an etch process such as a wet etch process is employed to remove the carrier wafer 9, the first memory-die backside dielectric layer 106 may be subsequently employed as an etch stop material layer. End surfaces of the through-stack via structures 486 may be physically exposed upon removal of the carrier wafer 9.

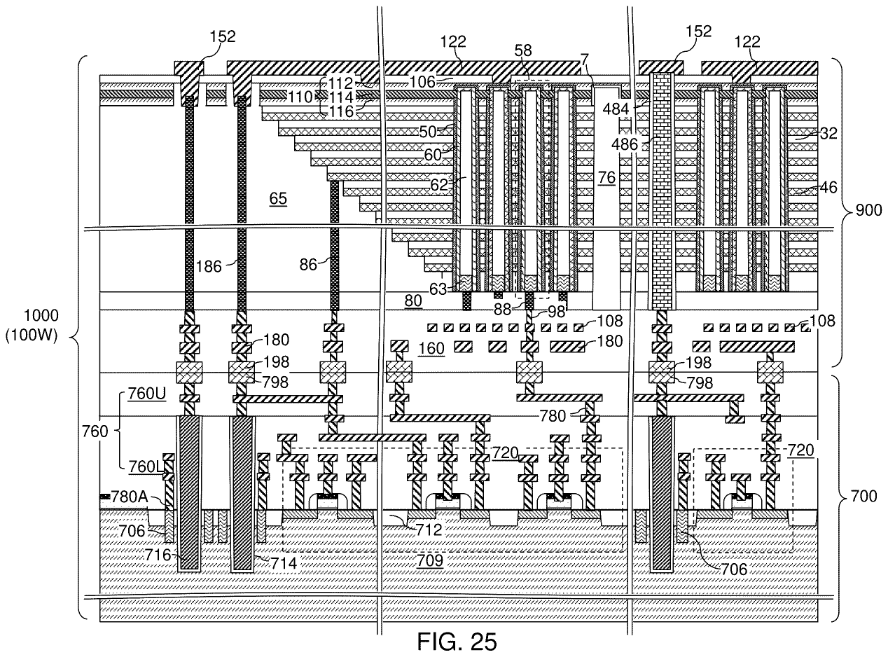

Referring to FIG. 24, backside via openings can be formed through the first memory-die backside dielectric layer 106 on the backside of the source layer 110 by performing a combination of a lithographic patterning process and an anisotropic etch process. Additional backside via openings can be formed through the first memory-die backside dielectric layer 106 and through the source layer 110 over the end portions of the peripheral connection via structures 186 by performing a combination of an additional lithographic patterning process and an additional anisotropic etch process.

Referring to FIG. 25, at least one electrically conductive material can be deposited in the backside via openings, over the physically exposed surface of the first memory-die backside dielectric layer 106, and over physically exposed end portions of the memory stack structures 55 to form a backside conductive layer. The at least one electrically conductive material may comprise a combination of a metallic barrier material (such as TiN, TaN, WN, and/or MoN) and an aluminum-based material comprising aluminum at an atomic percentage greater than 90 %. The backside conductive layer can be subsequently patterned to form various memory-die backside metal interconnect structures (122, 152).

In one embodiment, the memory-die backside metal interconnect structures (122, 152) may comprise at least one source connection structure 122 and memory-die backside connection pads 152. Each of the at least one source connection structure 122 may be electrically connected to a respective source line driver through a respective metal via structure 186 vertically extending through the retro-stepped dielectric material portion 65, a respective subset of the memory-die metal interconnect structures 180, a respective bonded pair of a logic-die intra-assembly bonding pad 798 and a memory-die intra-assembly bonding pad 198, and a respective subset of the logic-die metal interconnect structures 780. Each source connection structure 122 is electrically connected to the end portions of a respective subset of the memory stack structures 55 (e.g., to source side end portions of the vertical semiconductor channels 60). Each of the peripheral connection via structures 186 may be physically and/or electrically connected to a respective one of the memory-die backside connection pads 152 or the source connection structure 122. Each of the through-stack via structures 486 may be physically and/or electrically connected to a respective one of the memory-die backside connection pads 152 or the source connection structure 122.

At least a subset of the memory-die backside connection pads 152 can be electrically connected to a respective electrical node of the memory controller circuit 720 through a respective peripheral connection via structure 186, a respective subset of the memory-die metal interconnect structures 180, a respective bonded pair of a logic-die intra-assembly bonding pad 798 and a memory-die intra-assembly bonding pad 198, and a respective subset of the logic-die metal interconnect structures 780. Optionally, an additional subset of the memory-die backside connection pads 152 can be electrically connected to a respective electrical node of the memory controller circuit 720 through a respective through-stack via structure 486, a respective subset of the memory-die metal interconnect structures 180, a respective bonded pair of a logic-die intra-assembly bonding pad 798 and a memory-die intra-assembly bonding pad 198, and a respective subset of the logic-die metal interconnect structures 780.

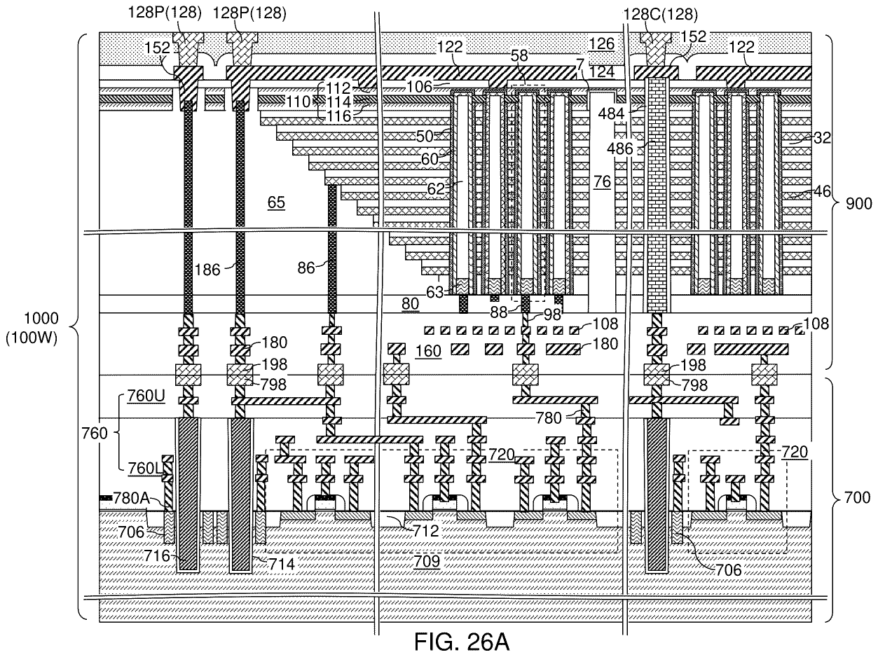

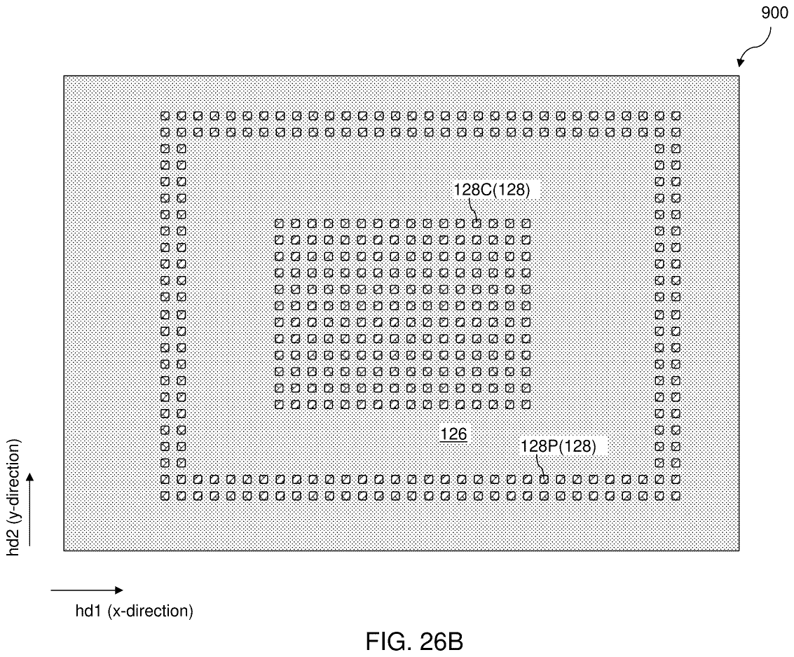

Referring to FIGS. 26A and 26B, a second memory-die backside dielectric layer 124 can be formed over the at least one source connection structure 122 and the memory-die backside connection pads 152. The second memory-die backside dielectric layer 124 comprises at least one inorganic dielectric layer. For example, the second memory-die backside dielectric layer 124 may comprise a stack of a first silicon oxide passivation layer, a silicon nitride passivation layer, and a third silicon oxide passivation layer. Generally, any combination of one or more inorganic interlayer dielectric (ILD) material layers may be employed for the second memory-die backside dielectric layer 124. In one embodiment, the entirety of the first memory-die backside dielectric layer 106 and the second memory-die backside dielectric layer 124 may consist essentially of inorganic dielectric materials, such as silicon oxide, silicon nitride, silicon oxynitride, silicon carbonitride, and/or at least one dielectric metal oxide. The memory-die backside metal interconnect structures (122, 152) can be embedded within the first and second memory-die backside dielectric layers (106, 124).

A third memory-die backside dielectric layer 126 can be applied over the first and second memory-die backside dielectric layers (106, 124). According to an aspect of the present disclosure, the third memory-die backside dielectric layer 126 comprises a dielectric material that can be subsequently employed for a dielectric-to-dielectric bonding. A dielectric-to-dielectric bonding can be achieved by applying heat and/or pressure to a bonding interface between two dielectric materials of the same material composition or different material compositions. Exemplary polymer materials that may be employed for the third memory-die backside dielectric layer 126 comprise silicon oxide, polyimide, benzocyclobutene (BCB), or an epoxy-based resin. The third memory-die backside dielectric layer 126 may be deposited, for example, by spin coating or spray coating. The entirety of the top surface of the as-deposited third memory-die backside dielectric layer 126 may be planar, i.e., formed within a horizontal plane. Alternatively, a CMP process may be performed to planarize the top surface of the third memory-die backside dielectric layer 126. The thickness of the third memory-die backside dielectric layer 126 may be in a range from 1 micron to 15 microns, such as from 3 microns to 10 microns, although lesser and greater thicknesses may also be employed.

In one embodiment, the third memory-die backside dielectric layer 126 can be patterned to form openings over the areas of the memory-die backside connection pads 152 and the source connection structures 122. If the third memory-die backside dielectric layer 126 comprises a photosensitive material, the third memory-die backside dielectric layer 126 can be lithographically exposed and developed to form the openings therein. An anisotropic etch process can be performed to transfer the pattern of the openings in the third memory-die backside dielectric layer through the second memory-die backside dielectric layer 124. The memory-die backside connection pads 152 may be employed as etch stop structures. Pad cavities can be formed through the third memory-die backside dielectric layer 126 and the second memory-die backside dielectric layer 124.

A photoresist layer (not shown) can be applied over the third memory-die backside dielectric layer 126, and can be lithographically patterned to form openings therein. An anisotropic etch process can be performed to transfer the pattern of the openings in the photoresist layer through the third memory-die backside dielectric layer 126 and the second memory-die backside dielectric layer 124. The memory-die backside connection pads 152 and the source connection structures 122 may be employed as etch stop structures. Pad cavities can be formed through the third memory-die backside dielectric layer 126 and the second memory-die backside dielectric layer 124. Any remaining portion of the photoresist layer may be removed, for example, by ashing.

The pad cavities may comprise central memory-die pad cavities that overlie memory-die backside connection pads 152 and peripheral memory-die pad cavities. In one embodiment, each pad cavity may comprise a respective sidewall that laterally encloses a respective void and vertically extends straight from a top surface of a memory-die backside connection pad 152 to a top surface of the third memory-die backside dielectric layer 126.

At least one electrically conductive material can be deposited in the pad cavities. The at least one electrically conductive material may comprise a combination of a metallic barrier material (such as TiN, TaN, WN, or MoN) and a metal fill material (such as Cu). Excess portions of the at least one electrically conductive material can be removed from above the horizontal plane including the top surface of the third memory-die backside dielectric layer 126. Memory-die inter-assembly bonding pads 128 can be formed within the volumes of the pad cavities.

The memory-die inter-assembly bonding pads 128 may comprise central memory-die inter-assembly bonding pads 128C that are formed in a center region and peripheral memory-die inter-assembly bonding pads 128P that are formed in a peripheral region. A subset of the central memory-die inter-assembly bonding pads 128C may contact a first subset of the memory-die backside connection pads 152 and are electrically connected to a respective one of the through-stack via structures 486. A subset of the peripheral memory-die inter-assembly bonding pads 128P may contact a second subset of the memory-die backside connection pads 152 that are electrically connected to the peripheral connection via structures 186. One or more of the memory-die inter-assembly bonding pads 128 may be formed on a respective one of the at least one source connection structure 122. In one embodiment, each memory-die inter-assembly bonding pad 128 may comprise a respective sidewall that vertically extends straight from a top surface of an memory-die backside connection pad 152 to a top surface of the third memory-die backside dielectric layer 126.

Memory-die inter-assembly bonding pads 128 in each memory die 900 are embedded within the memory-die backside dielectric layers (106, 124, 126). In one embodiment, a subset of the memory-die inter-assembly bonding pads 128 is electrically connected to the at least one source connection structure 122. The memory-die inter-assembly bonding pads 128 are configured for metal-to-metal bonding. In one embodiment, the memory-die inter-assembly bonding pads 128 may comprise copper pads configured for copper-to-copper bonding.

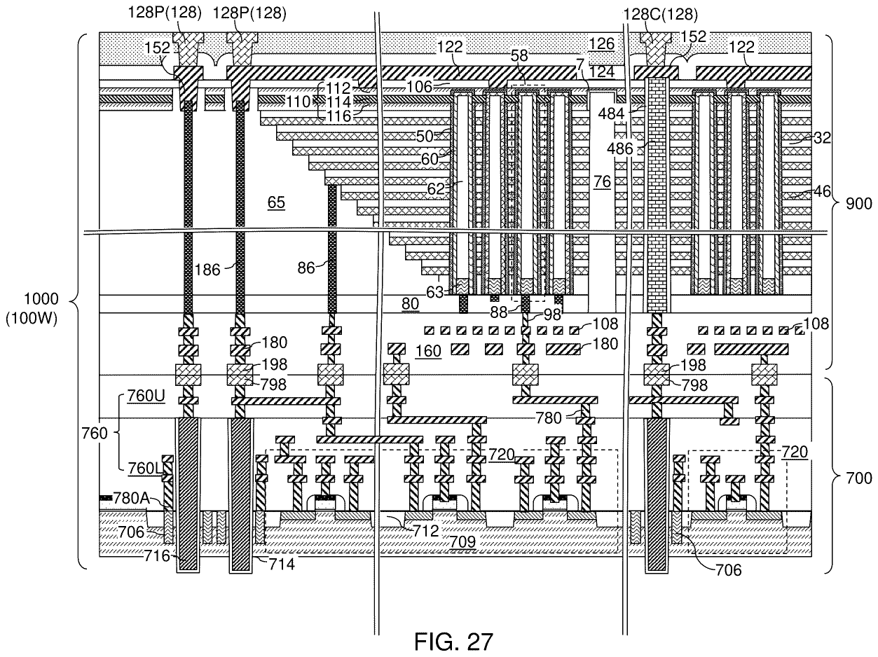

Referring to FIG. 27, the substrate semiconductor layer 709 of the logic die 700 can be thinned from the backside by performing at least one backside thinning process. The at least one backside thinning process may comprise grinding, polishing, an anisotropic etch process, and/or an isotropic etch process. Bottom surfaces of the dielectric liners 714 and/or the through-substrate via structures 716 may be employed as stopper structures during the at least one backside thinning process. The backside surface of the substrate semiconductor layer 709 can be vertically recessed until the bottom surfaces of the dielectric liners 714 are exposed or until the bottom surfaces of the through-substrate via structures 716 are exposed.

Subsequently, an optional selective etch process may be performed to recess the physically exposed backside surface of the substrate semiconductor layer 709 without etching the through-substrate via structures 716 and/or without etching the dielectric liners 714. For example, a wet etch process employing TMAH or TMY can be performed to vertically recess the backside surface of the substrate semiconductor layer 709. The vertical recess distance of the selective etch process may be in a range from 50 nm to 1,000 nm, although lesser or greater vertical recess distances may also be employed.

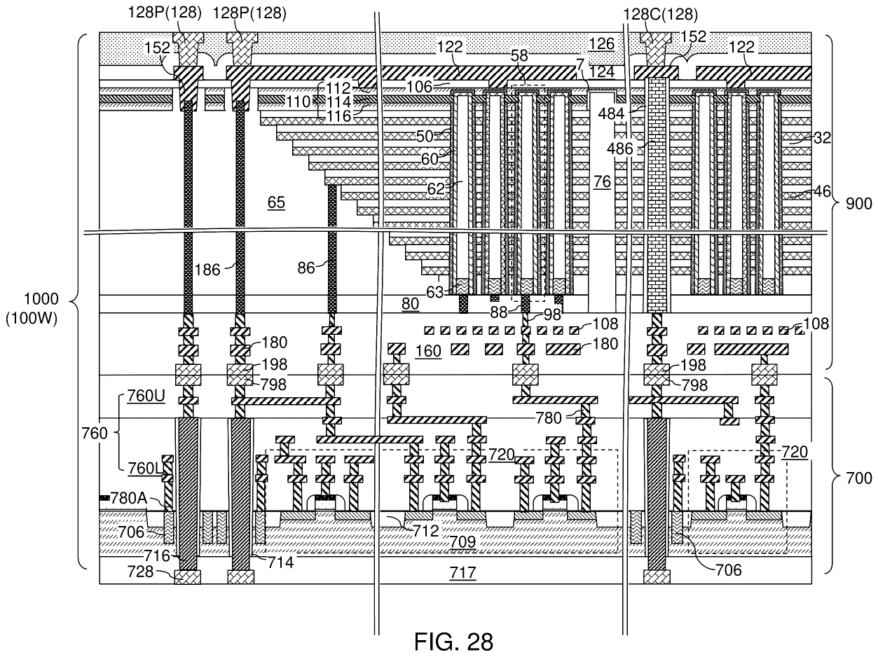

Referring to FIG. 28, a dielectric material can be deposited over the backside surface of the substrate semiconductor layer 709. The dielectric material may comprise a material that may be subsequently employed for dielectric-to-dielectric bonding. The dielectric material may be planarized to provide a planar physically exposed backside surface. The remaining portion of the dielectric material constitutes a logic-die backside dielectric layer 717. Pad cavities can be formed through the logic-die backside dielectric layer 717 in the areas of the through-substrate via structures 716. At least one electrically conductive material can be deposited in the pad cavities, and a planarization process can be performed to remove portions of the at least one electrically conductive material from outside the pad cavities. Remaining portions of the at least one electrically conductive material filling the pad cavities comprise logic-die inter-assembly bonding pads 728, which are embedded in the logic-die backside dielectric layer 717 and configured for metal-to-metal bonding. In one embodiment, the logic-die inter-assembly bonding pads 728 may comprise copper pads configured for copper-to-copper bonding.

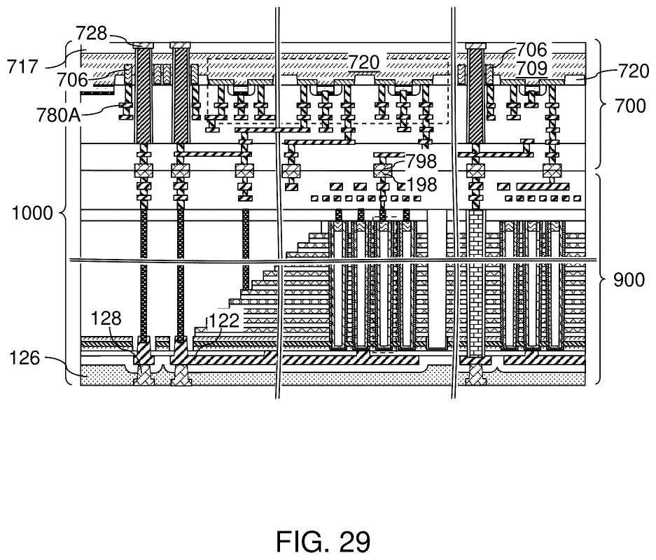

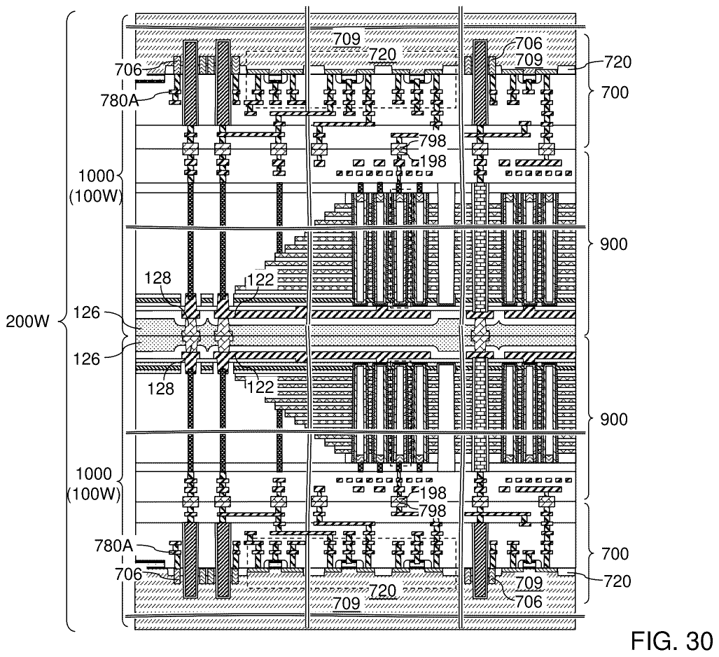

Referring to FIG. 29, a first exemplary bonded assembly 1000 is illustrated, which can be obtained by dicing the bonded wafer assembly 100W of the memory wafer 9 and the logic wafer 709 along dicing channels. Multiple unit bonded assemblies 1000 can be obtained by dicing the bonded wafer assembly 100W. The first exemplary bonded assembly 1000 is one of such diced unit bonded assemblies 1000. In this case, each unit bonded assembly 1000 may be employed as combination logic and memory dies that may be employed for die-to-wafer or die-to-die bonding or for direct attachment to an external system-level controller die or to an interposer.

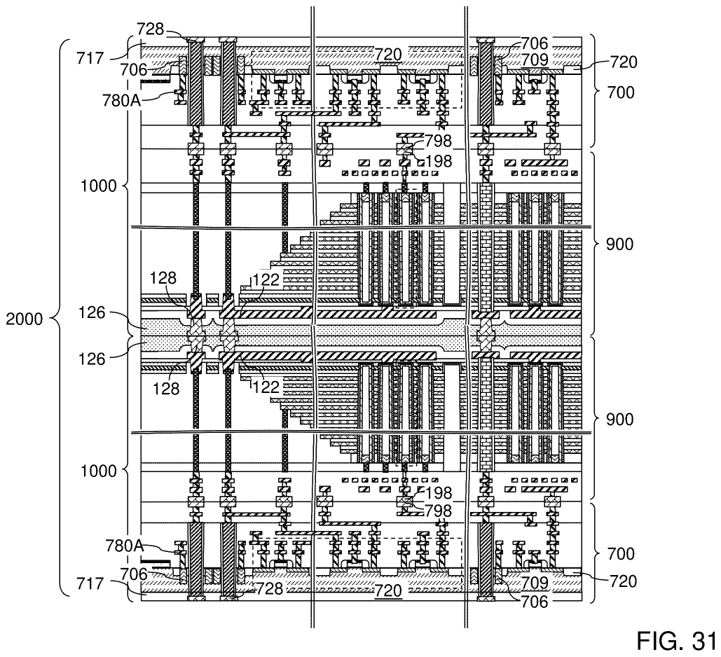

Referring to FIG. 30, a second exemplary bonded wafer assembly 200W according to a second embodiment of the present disclosure is illustrated. The second exemplary bonded wafer assembly 200W may be obtained by providing two instances of the first exemplary bonded wafer assembly 100W illustrated in FIGS. 26A and 26B, and by bonding the two instances of the first exemplary bonded wafer assembly 100W such that the memory-die inter-assembly bonding pads 128 of the first instance of the bonded wafer assembly 100W are bonded to the memory-die inter-assembly bonding pads 128 of the second instance of the bonded wafer assembly 100W by wafer-to-wafer bonding employing metal-to-metal bonding.

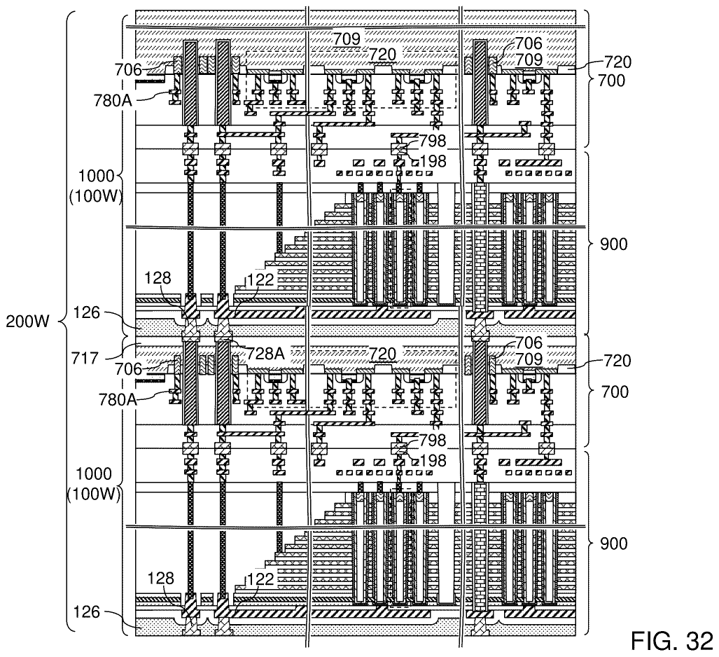

Referring to FIG. 31, the processing steps described with reference to FIGS. 27 and 28 can be performed for each of the logic dies 700 within the second exemplary bonded wafer assembly 200W to form logic-die inter-assembly bonding pads 728 on each logic die 700.

Subsequently, a dicing process may be performed to form a plurality of vertically bonded stacks 2000, which are combination logic and memory dies. A vertically bonded stack 2000 is illustrated in FIG. 31.

Alternatively, at least one additional memory wafer and at least one additional logic wafer can be bonded to the second exemplary bonded wafer assembly 200W after formation of the logic-die inter-assembly bonding pads 728 on each logic die 700. In this case, a bonded wafer assembly including vertical stacks of at least three memory wafers and at least three logic wafers can be formed. Suitable processing steps can be performed to form additional logic-die inter-assembly bonding pads 728 on outermost logic dies 700. Subsequently, a dicing process can be performed to dice the bonded wafer assembly including vertical stacks of at least three memory wafers and at least three logic wafers into a plurality of vertically bonded stacks, each of which comprises a composite semiconductor die.

Referring to FIG. 32, a third exemplary bonded wafer assembly 200W according to third embodiment of the present disclosure is illustrated. The third exemplary bonded wafer assembly 200W may be obtained by providing the first exemplary bonded wafer assembly 100W illustrated in FIGS. 26A and 26B as a first instance of the first exemplary bonded wafer assembly 100W, by providing the first exemplary bonded wafer assembly 100W illustrated in FIG. 28 as a second instance of the first exemplary bonded wafer assembly 100W, and by bonding the two instances of the first exemplary bonded wafer assembly 100W such that the memory-die inter-assembly bonding pads 128 of the first instance of the bonded wafer assembly 100W are bonded to the logic-die inter-assembly bonding pads 728 of the second instance of the bonded wafer assembly 100W by wafer-to-wafer bonding employing metal-to-metal bonding.

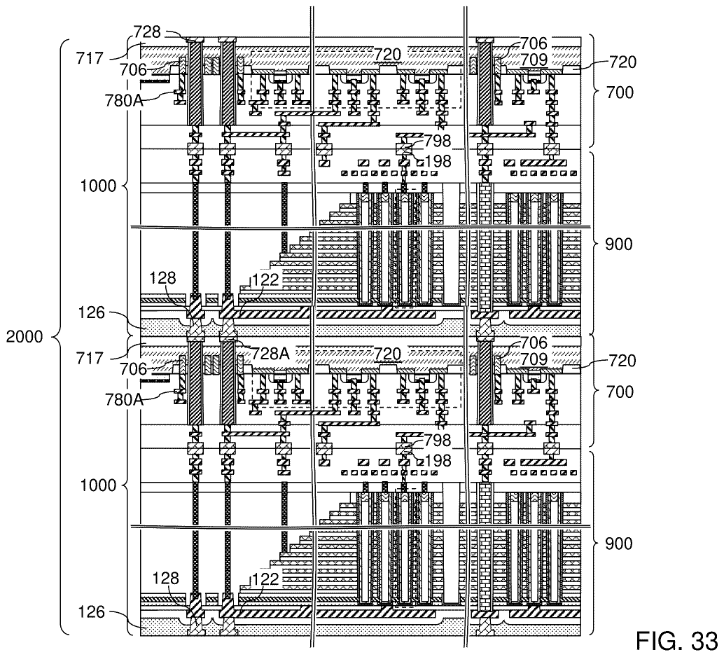

Referring to FIG. 33, the processing steps described with reference to FIGS. 27 and 28 can be performed for the logic dies 700 within the first instance of the first exemplary bonded wafer assembly 100W to form logic-die inter-assembly bonding pads 728 on the logic die 700.

Subsequently, a dicing process may be performed to form a plurality of vertically bonded stacks 2000, which are combination logic and memory dies. A vertically bonded stack 2000 is illustrated in FIG. 33.

Alternatively, at least one additional memory wafer and at least one additional logic wafer can be bonded to the third exemplary bonded wafer assembly 200W after formation of the logic-die inter-assembly bonding pads 728 on the logic die 700 of the first instance of the first exemplary bonded wafer assembly 100W. In this case, a bonded wafer assembly including vertical stacks of at least three memory wafers and at least three logic wafers can be formed. Suitable processing steps can be performed to form additional logic-die inter-assembly bonding pads 728 on outermost logic dies 700. Subsequently, a dicing process can be performed to dice the bonded wafer assembly including vertical stacks of at least three memory wafers and at least three logic wafers into a plurality of vertically bonded stacks, each of which comprises a composite semiconductor die.

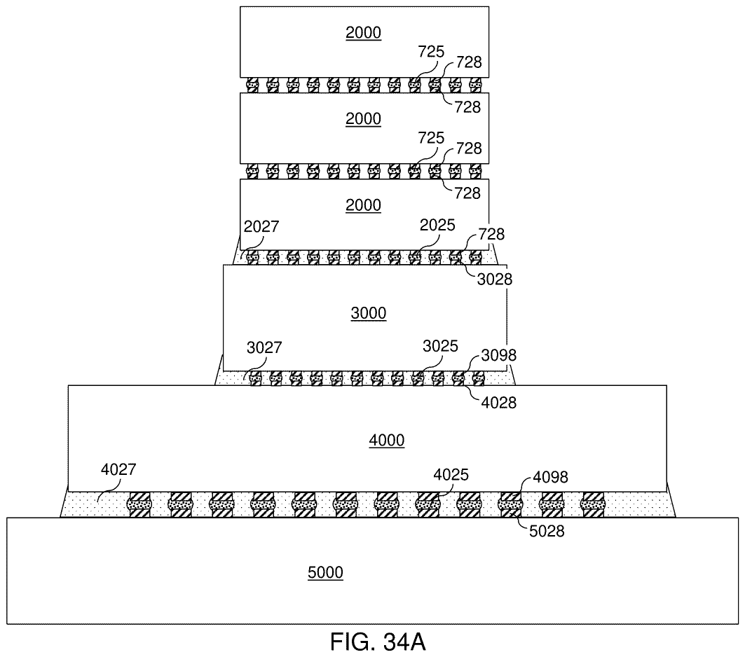

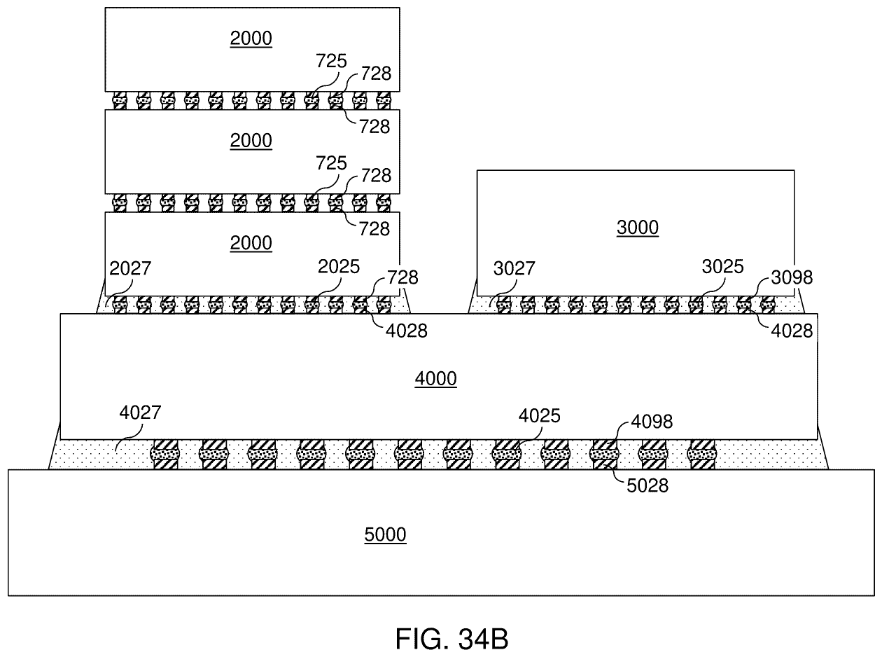

FIG. 34A is a vertical cross-sectional view of a first composite bonded assembly according to an embodiment of the present disclosure. FIG. 34B is a vertical cross-sectional view of a second composite bonded assembly according to an embodiment of the present disclosure. Referring collectively to FIGS. 34A and 34B, the vertically bonded stacks 2000 may be employed as high bandwidth flash memory assemblies. Each vertically bonded stack 2000 can be bonded to each other, and/or to a semiconductor package structure (3000, 4000, 5000) comprising package-die bump structures (3028, 4028) in various configurations such as the configurations illustrated in FIGS. 34A and 34B.

The first composite bonded assembly illustrated in FIG. 34A includes a vertical stack of multiple vertically bonded stacks 2000 (each of which functioning as a high bandwidth flash memory assembly) that are stacked along a vertical direction, an optional system-level controller die 3000, an optional interposer 4000, and a packaging substrate 5000 according to an embodiment of the present disclosure. The multiple instances of a vertically bonded stack 2000 are vertically stacked, and are bonded among one another through arrays of inter-memory solder material portions (e.g., micro-bump solder balls) 725. Each inter-memory solder material portion 725 may be bonded to a respective pair of logic-die backside bonding structures 728. The vertical stack of multiple vertically bonded stacks 2000 may be bonded to the system-level controller die 3000.

The second composite bonded assembly illustrated in FIG. 34B includes multiple instances of a vertically bonded stack 2000 that are stacked along a vertical direction, the optional system-level controller die 3000, the optional interposer 4000, and the packaging substrate 5000 according to an embodiment of the present disclosure. The vertical stack of multiple vertically bonded stacks 2000 may be bonded to the interposer 4000.

The system-level controller die 3000, if present, controls the operation of the logic dies 700 in each unit bonded assembly 1000 of the vertically bonded stack 2000. The system-level controller die 3000 may comprise at least one of a central processing unit (CPU), a graphics processing unit (GPU), a neural processing unit (NPU), and a digital signal processor (DSP). A bottommost instance of the vertically bonded stack 2000 may be bonded to the system-level controller die 3000 or to the interposer 4000 through an array of solder material portions 2025. In one embodiment, the logic-die backside bonding structures 728 of the bottommost instance of the vertically bonded stack 2000 may be bonded to top logic-die bump structures 3028 through an array of solder material portions 2025 as illustrated in FIG. 34A. Alternatively, the logic-die backside bonding structures 728 of the bottommost instance of the vertically bonded stack 2000 may be bonded to top interposer bump structures 4028 through an array of solder material portions 2025 as illustrated in FIG. 34B. An underfill material portion 2027 may be applied around the array of solder material portions 2025.

The interposer 4000 may comprise any type of interposer known in the art. For example, the packaging substrate 5000 may comprise a ceramic interposer or an organic interposer. The system-level controller die 3000 may be bonded to the interposer 4000 through an array of solder material portions 3025. For example, the bottom logic-die bump structures 3098 of the system-level controller die 3000 may be bonded to top interposer bump structures 4028 of the interposer 4000 through the array of solder material portions 3025. An underfill material portion 3027 may be applied around the array of solder material portions 3025.

The packaging substrate 5000 may comprise any type of packaging substrate known in the art. For example, the packaging substrate 5000 may comprise a cored packaging substrate, a non-cored packaging substrate, etc. The interposer 4000 may be bonded to the packaging substrate 5000 through an array of solder material portions 4025. For example, the bottom interposer bump structures 4098 of the interposer 4000 may be bonded to top substrate bump structures 5028 of the packaging substrate 5000 through the array of solder material portions 4025. An underfill material portion 4027 may be applied around the array of solder material portions 4025.

For each bonded assembly which may comprise a vertically bonded stack 2000, a semiconductor package structure (2000, 3000, 4000, 5000) comprising package-die bump structures (3028, 4028) may be provided. The first logic die 700 of the vertically bonded stack 2000 comprises logic-die inter-assembly bonding pads 728 located on an opposite side of the first logic-die copper bonding pads (as embodied as logic-die intra-assembly bonding pads 798). The package-die bump structures (3028, 4028) are bonded to the logic-die inter-assembly bonding pads 728 through an array of solder material portions 2025. In one embodiment, the semiconductor package structure (2000, 3000, 4000, 5000) comprises: an additional bonded assembly (e.g., an additional vertically bonded stack 2000) that comprises a third memory die 900 and a fourth memory die 900 that are bonded to each other through hybrid bonding; or a processor die (as embodied as a system-level controller die 3000) that comprises at least one of a central processing unit (CPU), a graphics processing unit (GPU), neural processing unit (NPU), and a digital signal processor (DSP).

Each composite bonded assembly 2000 may comprise a memory die pair (mDiP) assembly which includes two memory dies 900 and two logic dies 700. The mDiP functions as a chip which is then bonded to other mDiP chips and to the optional system-level controller die 3000, the optional interposer 4000, and the packaging substrate 5000, by various bonding structures, such as by micro-bumps, as shown in FIGS. 34A and 34B.

Referring to all drawings and according to various embodiments of the present disclosure, a semiconductor structure is provided, which comprises a vertically bonded stack 2000 of multiple unit bonded assemblies 1000 that are stacked along a vertical direction. Each unit bonded assembly 1000 of the multiple unit bonded assemblies 1000 comprises: a memory die 900 including an alternating stack (32, 46) of insulating layers 32 and electrically conductive layers 46, memory stack structures 55 vertically extending through the alternating stack (32, 46), a set of memory-die metal interconnect structures 980 embedded within a set of memory-die dielectric material layers 960, memory-die intra-assembly bonding pads 198, and memory-die inter-assembly bonding pads 128; and a logic die 700 including a controller circuit 720 configured to control operation of the memory stack structures 55 in the memory die 900, a set of logic-die metal interconnect structures 780 embedded within a set of logic-die dielectric material layers 760, logic-die intra-assembly bonding pads 798 that are bonded to the memory-die intra-assembly bonding pads 198, logic-die inter-assembly bonding pads 728, a logic-die substrate 709 on which the controller circuit 720 is located; through-substrate via structures 716 that vertically extend at least through the logic-die substrate 709, and a doped semiconductor well 706 laterally surrounding at least one of the through-substrate via structures 716.

In one embodiment, each of the through-substrate via structures 716 is surrounded one of a plurality of doped semiconductor wells 706. The plurality of doped semiconductor wells 706 comprise guard rings.

In one embodiment, the logic-die substrate comprises 709 a doped substrate semiconductor layer 709; the doped semiconductor well 706 has a doping type that is opposite of a doping type of the doped substrate semiconductor layer; and a p-n junction is present at an interface between the substrate semiconductor layer 709 and the doped semiconductor well 706. In one embodiment, the doped semiconductor well 706 is laterally spaced from said one of the through-substrate via structures 716 by a combination of a dielectric spacer 714 that laterally surrounds said one of the through-substrate via structures 716 and a portion of the substrate semiconductor layer 709. In one embodiment, the p-n junction is not in direct contact with the dielectric spacer 714.

In one embodiment, the logic die 700 within each unit bonded assembly 1000 also comprises a shallow trench isolation structure 712 located on a top portion of the substrate semiconductor layer 709 and laterally surrounding said one of the through-substrate via structures 716 and overlying the doped semiconductor well 706. In one embodiment, an inner sidewall of the doped semiconductor well 706 is in contact with one of the shallow trench isolation structures 712 and an outer sidewall of the doped semiconductor well 706 is in contact with another of the shallow trench isolation structures 712; and a bottom surface of the doped semiconductor well 706 is vertically spaced from a backside surface of the substrate semiconductor layer 709.

In one embodiment, the substrate semiconductor layer 709 includes electrical dopants of a first conductivity type at a first atomic concentration in a range from 1.0×10¹³/cm³ to 3.0×10¹⁷/cm³; and the doped semiconductor well 706 includes electrical dopants of a second conductivity type which is opposite of the first conductivity type at a second atomic concentration in a range from 1.0×10¹⁹/cm³ to 2.0×10²¹/cm³.

In one embodiment, the doped semiconductor well 706 is electrically connected to electrical ground of the logic die 700. Each vertically neighboring pair of unit bonded assemblies 1000 within the vertically bonded stack 2000 is bonded to each other by solder balls 725; and the logic-die intra-assembly bonding pads 798 are bonded to the memory-die intra-assembly bonding pads 198 by direct copper to copper bonding within each unit bonded assembly 1000.

In one embodiment, within each unit bonded assembly 1000, a memory-die dielectric material layer 960 within the set of memory-die dielectric material layers 960 is bonded to a logic-die dielectric material layer 760 within the set of logic-die dielectric material layers 760 by dielectric-to-dielectric bonding.

In one embodiment, the memory die 900 also comprises: a source layer 110 in contact with end portions of vertical semiconductor channels within the memory stack structures 55; and at least one source connection structure 122 in contact with a backside surface of the source layer 110. In one embodiment, a subset of the memory-die inter-assembly bonding pads 128 is electrically connected to the at least one source connection structure 122.

In one embodiment, the memory die 900 does not include a semiconductor substrate nor through-substrate via structures; and the memory stack structures 55 each comprise a vertical semiconductor channel 60 and a memory film 50.

In various embodiments, a semiconductor structure 2000 includes a first unit bonded assembly 1000 including a first memory die 900 bonded to a first logic die 700 by direct copper to copper bonding. The first logic die 700 includes first through-substrate via structures 716 laterally surrounded by first doped semiconductor well guard rings 706, and a second unit bonded assembly 1000 including a second memory die 900 bonded to a second logic die 700 by direct copper to copper bonding. The first unit bonded assembly 1000 is bonded to a second unit bonded assembly 1000 by solder balls 725.

In one embodiment, the first doped semiconductor well guard rings 706 are electrically connected to electrical ground of the first logic die 700; and the second logic die 700 comprises second through-substrate via structures 716 laterally surrounded by second doped semiconductor well guard rings 706 that are electrically connected to electrical ground of the second logic die.

The doped semiconductor wells 706 are configured to enhance signal integrity within the vertically bonded semiconductor stack by providing an electrically grounded path surrounding each through-substrate via structure 716. The doped semiconductor wells 706 create a low-impedance path to ground (V_{SS}), thereby forming an effective electromagnetic interference (EMI) shield around each through-substrate via structure 716. In one embodiment, the doped semiconductor wells 706 form guard rings around the through-substrate via structure 716,

An optional p-n junction may be formed between the doped semiconductor wells 706 and the surrounding substrate semiconductor layer 709 if they have opposite conductivity type. The p-n junction redirects substrate coupling noise away from adjacent active areas of the transistors of the circuit 720, reducing interference and preserving signal fidelity across the vertical signal paths. By mitigating inter-structure cross-talk, the doped semiconductor wells 706 decrease the keep-out zone between the through-substrate via structures 716 and nearby active devices (e.g., circuit 720), which allows for a more compact die layout and increases chip area efficiency.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a vertically bonded stack of multiple unit bonded assemblies that are stacked along a vertical direction, wherein each unit bonded assembly of the multiple unit bonded assemblies comprises:
a memory die including an alternating stack of insulating layers and electrically conductive layers, memory stack structures vertically extending through the alternating stack, a set of memory-die metal interconnect structures embedded within a set of memory-die dielectric material layers, memory-die intra-assembly bonding pads, and memory-die inter-assembly bonding pads; and
a logic die including a controller circuit configured to control operation of the memory stack structures in the memory die, a set of logic-die metal interconnect structures embedded within a set of logic-die dielectric material layers, logic-die intra-assembly bonding pads that are bonded to the memory-die intra-assembly bonding pads, logic-die inter-assembly bonding pads, a logic-die substrate on which the controller circuit is located, through-substrate via structures that vertically extend at least through the logic-die substrate, and a doped semiconductor well laterally surrounding at least one of the through-substrate via structures.

2. The semiconductor structure of claim 1, wherein each of the through-substrate via structures is surrounded one of a plurality of doped semiconductor wells.

3. The semiconductor structure of claim 2, wherein the plurality of doped semiconductor wells comprise guard rings.

4. The semiconductor structure of claim 3, wherein:
the logic-die substrate comprises a doped substrate semiconductor layer;
the doped semiconductor well has a doping type that is opposite of a doping type of the doped substrate semiconductor layer; and
a p-n junction is present at an interface between the substrate semiconductor layer and the doped semiconductor well.

5. The semiconductor structure of claim 4, wherein the doped semiconductor well is laterally spaced from said one of the through-substrate via structures by a combination of a dielectric spacer that laterally surrounds said one of the through-substrate via structures and a portion of the substrate semiconductor layer.

6. The semiconductor structure of claim 5, wherein the p-n junction is not in direct contact with the dielectric spacer.

7. The semiconductor structure of claim 4, wherein:
the logic die within each unit bonded assembly further comprises a shallow trench isolation structure located on a top portion of the substrate semiconductor layer and laterally surrounding said one of the through-substrate via structures;
an inner sidewall of the doped semiconductor well is in contact with a sidewall of the shallow trench isolation structure; and
a bottom surface of the doped semiconductor well is vertically spaced from a backside surface of the substrate semiconductor layer.

8. The semiconductor structure of claim 4, wherein:
the substrate semiconductor layer includes electrical dopants of a first conductivity type at a first atomic concentration in a range from 1.0×10¹³/cm³ to 3.0×10¹⁷/cm³; and
the doped semiconductor well includes electrical dopants of a second conductivity type which is opposite of the first conductivity type at a second atomic concentration in a range from 1.0×10¹⁹/cm³ to 2.0×10²¹/cm³.

9. The semiconductor structure of claim 1, wherein the doped semiconductor well is electrically connected to electrical ground of the logic die.

10. The semiconductor structure of claim 1, wherein:
each vertically neighboring pair of unit bonded assemblies within the vertically bonded stack is bonded to each other by solder balls; and
the logic-die intra-assembly bonding pads are bonded to the memory-die intra-assembly bonding pads by direct copper to copper bonding within each unit bonded assembly.

11. The semiconductor structure of claim 10, wherein a memory-die dielectric material layer within the set of memory-die dielectric material layers is bonded to a logic-die dielectric material layer within the set of logic-die dielectric material layers by dielectric-to-dielectric bonding.

12. The semiconductor structure of claim 1, wherein the memory die further comprises:
a source layer in contact with end portions of vertical semiconductor channels within the memory stack structures; and
at least one source connection structure in contact with a backside surface of the source layer, wherein a subset of the memory-die inter-assembly bonding pads is electrically connected to the at least one source connection structure.

13. The semiconductor structure of claim 1, wherein:
the memory die does not include a semiconductor substrate nor through-substrate via structures; and
the memory stack structures each comprise a vertical semiconductor channel and a memory film.

14. A semiconductor structure, comprising:
a first unit bonded assembly comprising a first memory die bonded to a first logic die by direct copper to copper bonding, wherein the first logic die comprises first through-substrate via structures laterally surrounded by first doped semiconductor well guard rings; and
a second unit bonded assembly comprising a second memory die bonded to a second logic die by direct copper to copper bonding, wherein the first unit bonded assembly is bonded to a second unit bonded assembly by solder balls.

15. The semiconductor structure of claim 14, wherein:
the first doped semiconductor well guard rings are electrically connected to electrical ground of the first logic die;
the second logic die comprises second through-substrate via structures laterally surrounded by second doped semiconductor well guard rings that are electrically connected to electrical ground of the second logic die;
the first memory die does not include a semiconductor substrate nor through-substrate via structures; and
the second memory die does not include a semiconductor substrate nor through-substrate via structures.

16. A method of forming a semiconductor structure, comprising:
bonding a first memory die to a first logic die by direct copper to copper bonding to form a first unit bonded assembly, wherein the first logic die comprises first through-substrate via structures laterally surrounded by first doped semiconductor well guard rings;
bonding a second memory die to a second logic die by direct copper to copper bonding to form a second unit bonded assembly; and
bonding the first unit bonded assembly to a second unit bonded assembly by solder balls.

17. The method of claim 16, wherein:
each of the first memory die and the second memory die comprises an alternating stack of insulating layers and electrically conductive layers, memory stack structures vertically extending through the alternating stack, a set of memory-die metal interconnect structures embedded within a set of memory-die dielectric material layers, memory-die intra-assembly bonding pads, and memory-die inter-assembly bonding pads; and
each of the first logic die and the second logic die comprises a controller circuit configured to control operation of the memory stack structures in a respective one of the first memory die and the second memory die, a set of logic-die metal interconnect structures embedded within a set of logic-die dielectric material layers, logic-die intra-assembly bonding pads that are bonded to the memory-die intra-assembly bonding pads, and logic-die inter-assembly bonding pads.

18. The method of claim 16, wherein:
the first memory die is located on a first memory wafer including the first memory die and additional first memory dies;
the first logic die is located on a first logic wafer including the first logic die and additional logic dies;
the second memory die is located on a second memory wafer including the second memory die and additional second memory dies; and
the second logic die is located on a second logic wafer including the second logic die and additional logic dies.

19. The method of claim 18, further comprising, prior to bonding the first unit bonded assembly to a second unit bonded assembly by solder balls:
bonding the first memory wafer to the first log wafer by copper to copper bonding between respective copper bonding pads;
dicing the bonded first memory wafer and the first logic wafer to form the first unit bonded assembly;
bonding the second memory wafer to the second logic wafer by copper to copper bonding between respective copper bonding pads; and
dicing the bonded second memory wafer and the second logic wafer to form the second unit bonded assembly.

20. The method of claim 16, wherein:
the first doped semiconductor well guard rings are electrically connected to electrical ground of the first logic die;
the second logic die comprises second through-substrate via structures laterally surrounded by second doped semiconductor well guard rings that are electrically connected to electrical ground of the second logic die;
the first memory die does not include a semiconductor substrate nor through-substrate via structures; and
the second memory die does not include a semiconductor substrate nor through-substrate via structures.
